(19) United States
(12) Patent Application Publication
(10) Pub. No.: US 2025/0234632 A1
(43) Pub. Date: Jul. 17, 2025

(54) SEMICONDUCTOR PROCESSING INTEGRATION FOR BIPOLAR JUNCTION TRANSISTOR (BJT)

(71) Applicant: TEXAS INSTRUMENTS INCORPORATED, Dallas, TX (US)

(72) Inventors: Jonathan Lane, Sandy, UT (US); Giulio Albini, Draper, UT (US); Hiroshi Yasuda, Plano, TX (US); Robert Cassel, Lehi, UT (US)

(21) Appl. No.: 18/411,331

(22) Filed: Jan. 12, 2024

(51) Int. Cl. H01L 21/8249; H01L 27/06

(52) U.S. Cl. CPC H10D 84/038; H10D 84/0109; H10D 84/401

(57) ABSTRACT

The present disclosure generally relates to semiconductor processing integration for a bipolar junction transistor (BJT). In an example, a semiconductor device includes a semiconductor substrate, a BJT, a field effect transistor (FET), and a composite structure. The semiconductor substrate includes a BJT region, a complementary FET (CFET) region, and a transition region between the BJT region and the CFET region. The BJT is on the semiconductor substrate in the BJT region. The FET is on the semiconductor substrate in the CFET region. The composite structure is on the semiconductor substrate in the transition region. The composite structure includes a material that is the same as a gate electrode of the FET.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate, a bipolar junction transistor (BJT), a field effect transistor (FET), and a composite structure. The semiconductor substrate includes a BJT region, a complementary FET (CFET) region, and a transition region between the BJT region and the CFET region. The BJT is on the semiconductor substrate in the BJT region. The FET is on the semiconductor substrate in the CFET region. The composite structure is on the semiconductor substrate in the transition region. The composite structure includes a material that is the same as a gate electrode of the FET.

Another example is a method. A gate layer is formed over a semiconductor substrate in a BJT region, a transition region, and a CFET region. The transition region is between the BJT region and the CFET region. An opening is formed through the gate layer at least partially in the BJT region and the transition region. A sidewall of the gate layer defining the opening is in the transition region. A collector layer is formed in the opening and on an upper surface of the semiconductor substrate in the BJT region. A base layer is formed on the collector layer. An emitter layer is formed on the base layer. After forming the emitter layer, the gate layer is patterned into a gate electrode of a FET in the CFET region.

A further example is a method. A pedestal dielectric layer is formed over a semiconductor substrate in a BJT region and at least partially in a transition region. The transition region is between the BJT region and a CFET region. A gate layer is formed over the semiconductor substrate in the BJT region, the transition region, and the CFET region and over the pedestal dielectric layer. A first opening is formed through the gate layer to the pedestal dielectric layer. A sidewall of the gate layer defining at least a portion of the first opening is over the pedestal dielectric layer in the transition region. Through the first opening, a second opening is formed through the pedestal dielectric layer to an upper surface of the semiconductor substrate in the BJT region. Through the first opening, a collector layer is formed in the second opening and on the upper surface of the semiconductor substrate. Through the first opening, a base layer is formed on the collector layer. Through the first opening, an emitter layer is formed on the base layer. The gate layer is patterned into a gate electrode of a FET in the FET region. After patterning the gate layer into the gate electrode of the FET, a portion of the gate layer remains in the transition region.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 40 are respective cross-sectional views of a semiconductor device in intermediate stages of manufacturing according to some examples.

FIG. 40A is a cross-sectional view of a portion of the semiconductor device of FIG. 40 according to some examples.

FIG. 41 is a layout view of overlaid openings and masks for intermediate stages of manufacturing according to some examples.

FIGS. 42 through 48 are respective cross-sectional views of a semiconductor device in intermediate stages of manufacturing according to some examples.

FIG. 48A is a cross-sectional view of a portion of the semiconductor device of FIG. 48 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing integration for a bipolar junction transistor (BJT). Some examples include a semiconductor device including a BJT. A semiconductor substrate includes a BJT region, a complementary field effect transistor (CFET) region, and a transition region between the BJT region and the CFET region. A BJT is on the semiconductor substrate in the BJT region, and a field effect transistor (FET) is on the semiconductor substrate in the CFET region. A composite structure is on the semiconductor substrate in the transition region. The composite structure includes a material that is the same as the gate electrode of the FET. Methods of fabricating such a semiconductor device are described. Generally, such methods of fabrication may have improved photolithography alignment specification, improved manufacturability, and ease of processing, as detailed subsequently. Other benefits and advantages may be achieved.

Various examples are described subsequently. Although the specific examples may illustrate various aspects of the above generally described features, examples may incorporate any combination of the above generally described features (which are described in more detail in examples below).

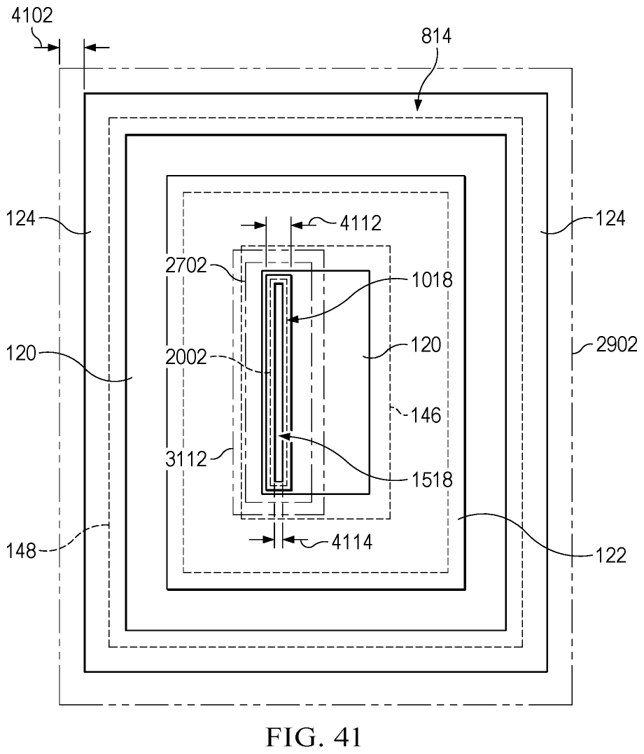

FIGS. 1 through 40 are respective cross-sectional views of a semiconductor device in intermediate stages of manufacturing according to some examples. FIG. 41 is a layout view of overlaid openings and masks (e.g., photoresists) for intermediate stages of manufacturing according to some examples.

Referring to FIG. 1, a semiconductor substrate 102 is provided. The semiconductor substrate 102 includes a BJT region 104, a first transition region 106, a second transition region 108, a p-type FET (pFET) region 110, and an n-type FET (nFET) region 112. Together, the pFET region 110 and the nFET region 112 are included in a complementary field effect transistor (CFET) region. As an example, a lower operating voltage rated pFET is formed in the pFET region 110 (e.g., as illustrated by a thinner gate dielectric layer subsequently), and a higher operating voltage rated nFET is formed in the nFET region 112 (e.g., as illustrated by a thicker gate dielectric layer subsequently). In other examples, a higher operating voltage rated pFET may alternatively or additionally be formed in the pFET region 110. In other examples, a lower operating voltage rated nFET may alternatively or additionally be formed in the nFET region 112.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the BJT, pFET, and nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 122 (including a first portion 122a and a second portion 122b), 124 (including a first portion 124a and a second portion 124b), 126, 128, 130 are formed on the semiconductor substrate 102. In the illustrated example, the isolation structures 122, 124, 126, 128, 130 are shallow trench isolation structures (STIs) extending from the upper surface 120 of the semiconductor substrate 102 into the semiconductor substrate 102. As illustrated, the isolation structures 122-130 are also raised above the upper surface 120 of the semiconductor substrate 102, and in other examples, the isolation structures 122-130 may have respective upper surfaces co-planar with and/or below the upper surface 120 of the semiconductor substrate 102. The isolation structures 122-130 may include, for example, a liner layer, such as including silicon oxide or silicon nitride, conformally along surfaces of a respective trench in the semiconductor substrate 102 and a fill isolation material, such as silicon oxide, over and on the liner layer.

The isolation structures 122-130, as illustrated, may be formed by depositing a hardmask layer over the semiconductor substrate 102. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 102 using the patterned hardmask layer as a mask. The liner layer may then be conformally deposited in the recesses or trenches and over the patterned hardmask layer, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 122-130 may be field oxide structures, such as local oxidation of silicon (LOCOS) structures, at the upper surface 120 of the semiconductor substrate 102, which may be formed using a LOCOS process.

The isolation structure 122 laterally defines an active area of the upper surface 120 of the semiconductor substrate 102 on which the BJT is to be formed. The isolation structure 122 laterally encircles or encompasses the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the first portion 122a of the isolation structure 122. Further, the isolation structure 124 defines lateral boundaries of the BJT region 104. The isolation structure 124 laterally encircles or encompasses the isolation structure 122 with a doped isolation or guardring well therebetween, as described subsequently.

The isolation structures 126, 128 laterally define, at least in part, an active area of the upper surface 120 of the semiconductor substrate 102 on which the pFET is to be formed. The active area of the upper surface 120 of the semiconductor substrate 102 on which the pFET is formed defines the lateral boundary of the pFET region 110. Similarly, the isolation structures 128, 130 laterally define, at least in part, an active area of the upper surface 120 of the semiconductor substrate 102 on which the nFET is to be formed. The active area of the upper surface 120 of the semiconductor substrate 102 on which the nFET is formed defines the lateral boundary of the nFET region 112. The CFET region includes the pFET region 110 and the nFET region 112. The laterally exterior boundaries of the pFET region 110 and/or nFET region 112 (or other pFET and/or nFET regions) define the lateral boundary of the CFET region.

The first transition region 106 is defined from a lateral boundary of the BJT region 104 to a nearest lateral boundary of the CFET region (which in the illustrated example is a boundary of the pFET region 110). The first transition region 106 includes the first portion 124a of the isolation structure 124. As illustrated, a portion of the upper surface 120 of the semiconductor substrate 102 is between the first portion 124a of the isolation structure 124 and the isolation structure 126 in the first transition region 106. In other examples, the first transition region 106 may have an isolation structure laterally throughout the first transition region 106. The second transition region 108 is defined from a lateral boundary of the BJT region 104 to a nearest lateral boundary of another region (not illustrated). The second transition region 108 includes the second portion 124b of the isolation structure 124. As illustrated, a portion of the upper surface 120 of the semiconductor substrate 102 extends from the second portion 124b of the isolation structure 124 in the second transition region 108. In other examples, the second transition region 108 may have an isolation structure laterally throughout the second transition region 108.

An n-type doped well 144 is formed in the semiconductor substrate 102. The n-type doped well 144 may be formed by masking (e.g., by a photoresist using photolithography) areas of the semiconductor substrate 102 where an n-type doped well is not to be formed and implanting n-type dopants into the semiconductor substrate 102. The n-type doped well 144 extends from the upper surface 120 of the semiconductor substrate 102 into a depth in the semiconductor substrate 102 and is in the pFET region 110 laterally between the isolation structures 126, 128. A concentration of the n-type dopant of the n-type doped well 144 is greater than a concentration of the p-type dopant of the p-type doped semiconductor substrate 102. In some examples, the n-type doped well 144 is doped with an n-type dopant (e.g., phosphorus (P) or arsenic (As)) with a concentration in a range from 1×10¹⁵ cm⁻³ to 1×10¹⁷ cm⁻³. Another dopant type and/or other doping concentrations may be implemented.

An n-type doped sub-collector diffusion region 146 is formed in the semiconductor substrate 102 laterally between the portions 122a, 122b of the isolation structure 122. The n-type doped sub-collector diffusion region 146 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 146 extends from the upper surface 120 of the semiconductor substrate 102 into a depth in the semiconductor substrate 102 and is in the BJT region 104 laterally between the portions 122a, 122b of the isolation structure 122. A concentration of the n-type doped sub-collector diffusion region 146 is greater than a concentration of the p-type dopant of the semiconductor substrate 102. In some examples, the n-type doped sub-collector diffusion region 146 is doped with an n-type dopant with a concentration in a range from 1×10¹⁸ cm⁻³ to 1×10²⁰ cm⁻³. Another dopant type and/or other doping concentrations may be implemented.

P-type doped wells 148, 150 are formed in the semiconductor substrate 102. The p-type doped wells 148, 150 may be formed by masking (e.g., by a photoresist using photolithography) areas of the semiconductor substrate 102 where a p-type doped well is not to be formed and implanting p-type dopants into the semiconductor substrate 102. The p-type doped well 148 extends from the upper surface 120 of the semiconductor substrate 102 into a depth in the semiconductor substrate 102 and is in the BJT region 104 laterally between the isolation structures 122, 124. The p-type doped well 148 is an isolation ring or guardring laterally encircling or encompassing the active area in which the BJT is to be formed. The p-type doped well 150 extends from the upper surface 120 of the semiconductor substrate 102 into a depth in the semiconductor substrate 102 and is in the nFET region 112 laterally between the isolation structures 128, 130. A concentration of the p-type dopant of the p-type doped wells 148, 150 is greater than a concentration of the p-type dopant of the p-type doped semiconductor substrate 102. In some examples, the p-type doped wells 148, 150 are doped with a p-type dopant (e.g., boron (B)) with a concentration in a range from 1×10¹⁵ cm⁻³ to 1×10¹⁷ cm⁻³. Another dopant type and/or other doping concentrations may be implemented.

Referring to FIG. 41, the n-type doped sub-collector diffusion region 146 and the p-type doped well 148 are shown (e.g., by dashed line boundaries) in a layout view of the BJT region 104 and neighboring portions of the transition regions 106, 108. Additionally, the isolation structures 122, 124 are shown (e.g., by solid line boundaries) with the upper surface 120 of the semiconductor substrate 102 shown between the isolation structures 122, 124, as well as within the isolation structure 122. The boundaries of the n-type doped sub-collector diffusion region 146 and the p-type doped well 148 may correspond to openings through respective masks (e.g., photoresist) used during corresponding implantations of dopants.

Although the semiconductor substrate 102, n-type doped well 144, n-type doped sub-collector diffusion region 146, and p-type doped wells 148, 150 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

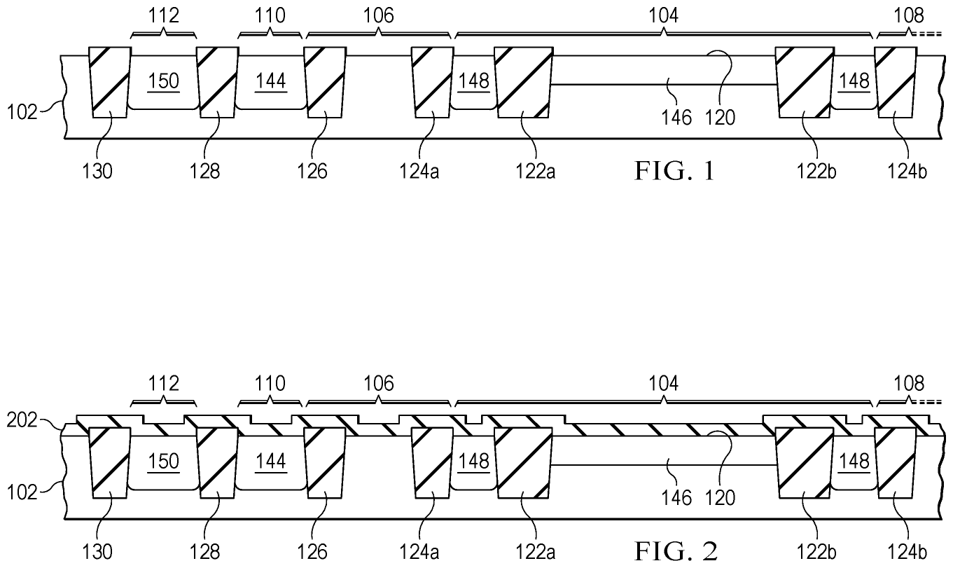

Referring to FIG. 2, a pedestal dielectric layer 202 is formed over the semiconductor substrate 102. The pedestal dielectric layer 202 is conformally deposited over the upper surface 120 of the semiconductor substrate 102 and the isolation structures 122-130. In some examples, the pedestal dielectric layer 202 is silicon oxide (e.g., a tetraethyl orthosilicate (TEOS) oxide) deposited by CVD, although other dielectric materials and/or other deposition processes may be used in other examples.

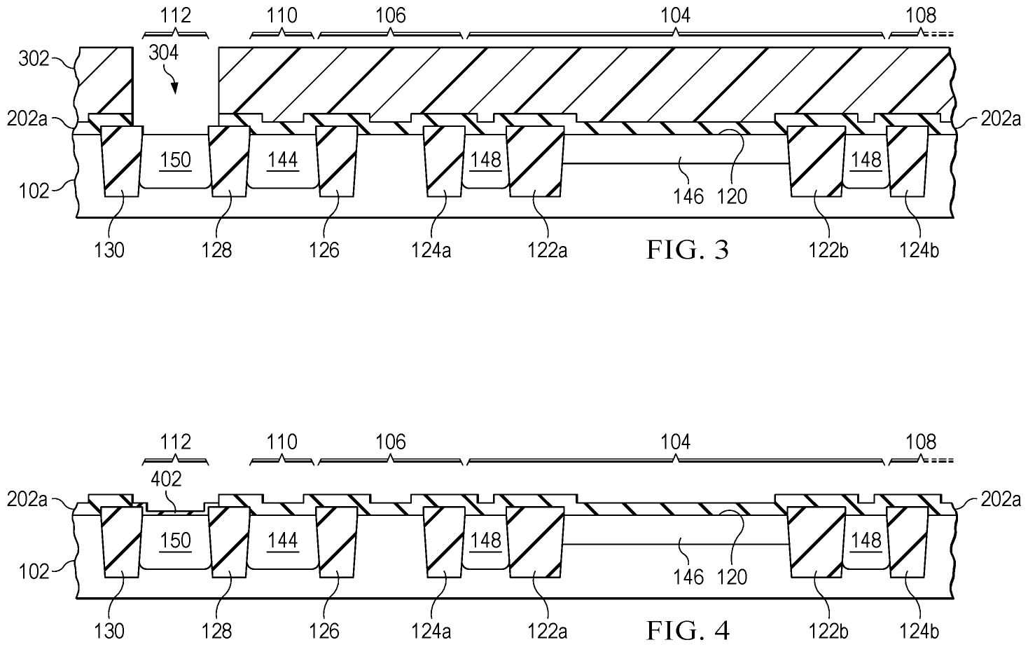

Referring to FIG. 3, the pedestal dielectric layer 202 is removed from the upper surface 120 of the semiconductor substrate 102 in the nFET region 112 such that pedestal dielectric layer 202a remains in other regions. In the illustrated example, the portion of the pedestal dielectric layer 202 is removed using appropriate photolithography and etch processes. A photoresist 302 is deposited (e.g., by spin-on) on or over the pedestal dielectric layer 202 and patterned using photolithography. The photoresist 302 is patterned to remain in regions in which the pedestal dielectric layer 202 is to remain and to have an opening 304 exposing the portion of the pedestal dielectric layer 202 in the nFET region 112 that is to be removed. With the patterned photoresist 302, an etch process, such as an anisotropic etch like an RIE or the like, is performed, using the patterned photoresist 302 as a mask, to remove the exposed portion of the pedestal dielectric layer 202 and to pattern the pedestal dielectric layer 202 into the pedestal dielectric layer 202a. After the etch process, the photoresist 302 is removed, such as by ashing.

Referring to FIG. 4, a gate dielectric layer 402 is formed on or over the upper surface 120 of the semiconductor substrate 102 in the nFET region 112. In some examples, the gate dielectric layer 402 may be silicon oxide formed using oxidation, such as by in situ steam generation (ISSG) oxidation or another oxidation process. In other examples, another dielectric material and/or another deposition process may be used to form the gate dielectric layer 402.

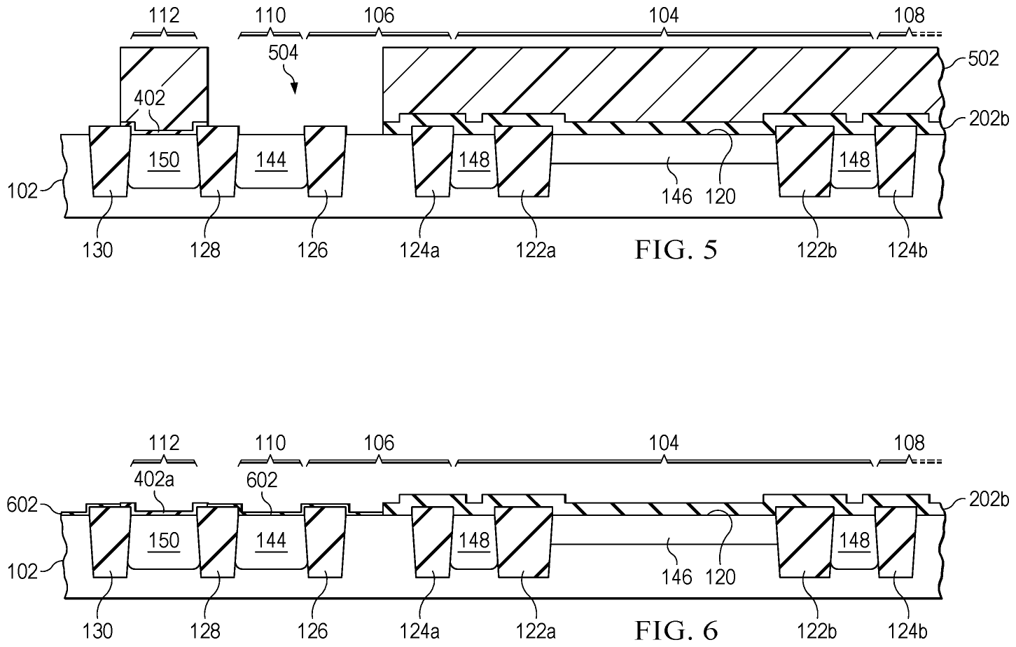

Referring to FIG. 5, the pedestal dielectric layer 202a is removed from the upper surface 120 of the semiconductor substrate 102 in the pFET region 110 and, possibly, in a portion of the first transition region 106 such that pedestal dielectric layer 202b remains in other regions (e.g., in the BJT region 104 and extending into the first transition region 106). In the illustrated example, the portion of the pedestal dielectric layer 202a is removed using appropriate photolithography and etch processes. A photoresist 502 is deposited (e.g., by spin-on) on or over the pedestal dielectric layer 202a and gate dielectric layer 402 and patterned using photolithography. The photoresist 502 is patterned to remain in regions in which the pedestal dielectric layer 202a and the gate dielectric layer 402 are to remain and to have an opening 504 exposing the portion of the pedestal dielectric layer 202a in the pFET region 110 (and possibly, a portion of the first transition region 106) that is to be removed. With the patterned photoresist 502, an etch process, such as an anisotropic etch like an RIE or the like, is performed, using the patterned photoresist 502 as a mask, to remove the exposed portion of the pedestal dielectric layer 202a and to pattern the pedestal dielectric layer 202a into the pedestal dielectric layer 202b. After the etch process, the photoresist 502 is removed, such as by ashing.

Referring to FIG. 6, a gate dielectric layer 602 is formed on or over the upper surface 120 of the semiconductor substrate 102 in the pFET region 110 (and possibly, in a portion of the first transition region 106). In some examples, the gate dielectric layer 602 may be silicon oxide formed using oxidation, such as by ISSG oxidation or another oxidation process. In the illustrated example, the gate dielectric layer 602 is formed using oxidation, which further oxidizes the semiconductor substrate 102 at the gate dielectric layer 402. The oxidation of the semiconductor substrate 102 at the gate dielectric layer 402 results in an increased thickness of the gate dielectric layer 402a. The gate dielectric layer 402a has a greater thickness than the gate dielectric layer 602. In other examples, another dielectric material and/or another deposition process may be used to form the gate dielectric layer 602.

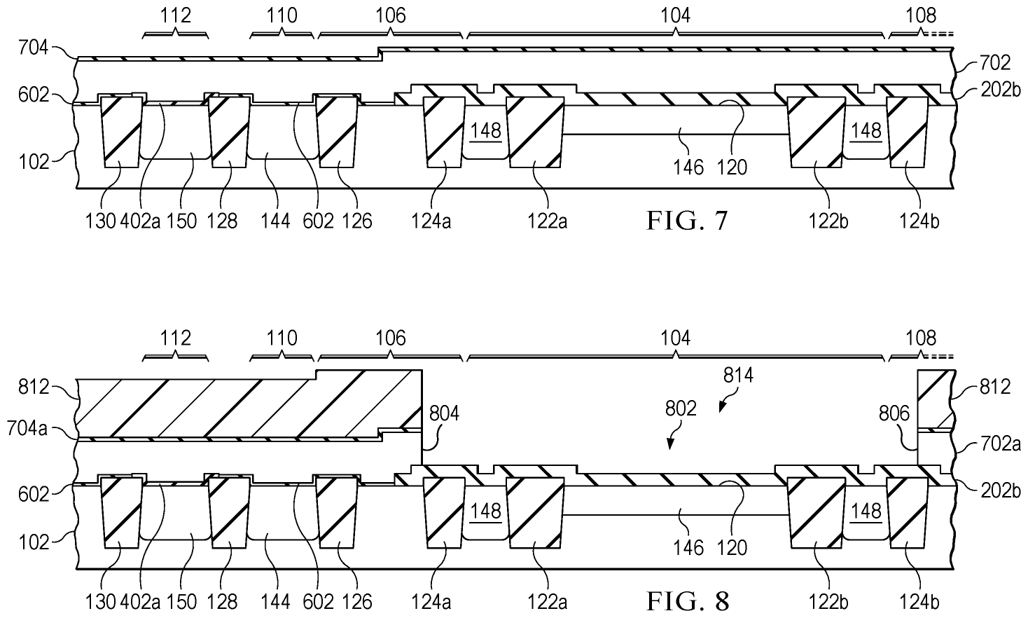

Referring to FIG. 7, a gate layer 702 is formed over the semiconductor substrate 102, and a dielectric protective layer 704 is formed over the gate layer 702. The gate layer 702 is formed over the gate dielectric layers 402a, 602 and the pedestal dielectric layer 202b. In some examples, the gate layer 702 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. In some examples, the gate layer 702 in the BJT region 104, transition regions 106, 108, and pFET region 110 is polysilicon doped with a p-type dopant with a concentration in a range from 1×10¹⁹ cm⁻³ to 1×10²¹ cm⁻³ after deposition and/or implantation, and the gate layer 702 in the nFET region 112 is polysilicon doped with an n-type dopant with a concentration in a range from 5×10¹⁹ cm⁻³ to 5×10²¹ cm⁻³ after implantation. Other materials (e.g., conductive material) may be implemented as the gate layer 702, which may be formed by any deposition process. In some examples, the dielectric protective layer 704 is silicon oxide (e.g., a TEOS oxide) deposited by CVD, although other dielectric materials and/or other deposition processes may be used in other examples.

Referring to FIG. 8, the dielectric protective layer 704 and gate layer 702 are etched to form an opening 802 through the dielectric protective layer 704a and gate layer 702a to the pedestal dielectric layer 202b. The opening 802 is in the BJT region 104 and the transition regions 106, 108. The opening 802 is defined, at least in part, by sidewalls 804, 806 of the gate layer 702a (and further by corresponding sidewalls of the dielectric protective layer 704a, which are not indicated by a reference numeral). The sidewall 804 of the gate layer 702a is over the pedestal dielectric layer 202b in the first transition region 106. The sidewall 806 of the gate layer 702a is over the pedestal dielectric layer 202b in the second transition region 108. As will be shown subsequently, the BJT is formed through the opening 802 through the gate layer 702a. The formation of the opening 802 results in the gate layer 702 being removed from the BJT region 104.

In the illustrated example, the dielectric protective layer 704 and gate layer 702 are patterned using appropriate photolithography and etch processes. A photoresist 812 is deposited (e.g., by spin-on) on or over the dielectric protective layer 704 and patterned using photolithography. The photoresist 812 is patterned to remain in regions in which the dielectric protective layer 704 and gate layer 702 are to remain and to have an opening 814 (corresponding to the opening 802) exposing the portion of the dielectric protective layer 704 in the BJT region 104 and the transition regions 106, 108 that is to be removed. The opening 814 (which may correspond to the outer boundary of the isolation structure 124) is shown in the layout view in FIG. 41. With the patterned photoresist 812, an etch process, such as an anisotropic etch like an RIE or the like, is performed, using the patterned photoresist 812 as a mask, to remove portions of the dielectric protective layer 704 and gate layer 702 and to pattern the dielectric protective layer 704 and gate layer 702 into the dielectric protective layer 704a and gate layer 702a, respectively. As indicated by FIGS. 8 and 41, resulting sidewalls (including sidewalls 804, 806) of the gate layer 702a are disposed in transition regions (including transition regions 106, 108) encompassing the BJT region 104. After the etch process, the photoresist 812 is removed, such as by ashing.

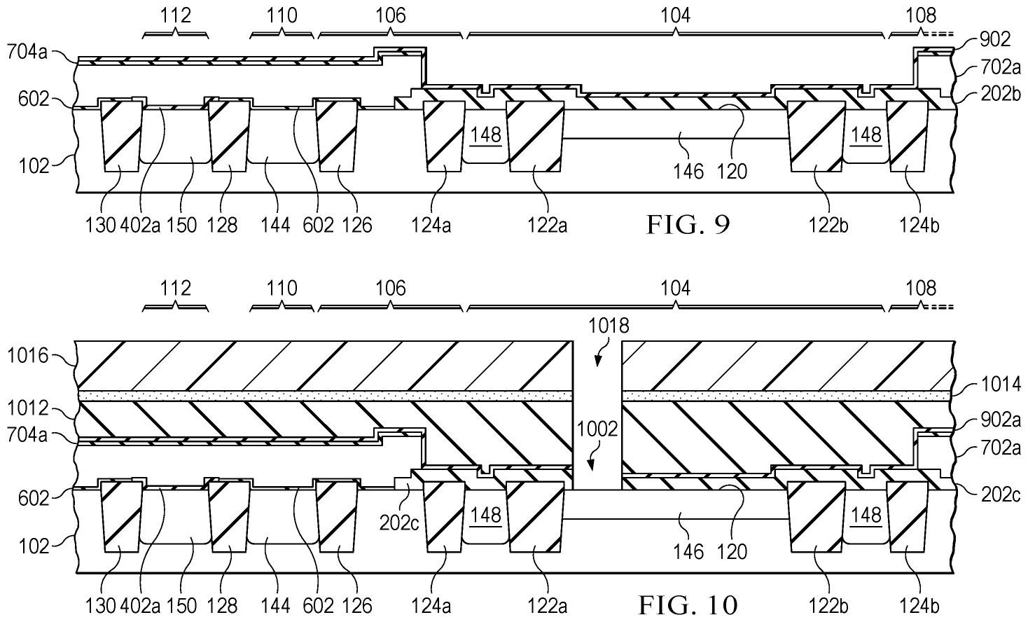

Referring to FIG. 9, a hardmask layer 902 is formed conformally over the semiconductor substrate 102. The hardmask layer 902 is conformally over the dielectric protective layer 704a, along the sidewalls 804, 806, and over the pedestal dielectric layer 202b exposed through the opening 802. In some examples, the hardmask layer 902 is or includes silicon nitride deposited by CVD, although other hardmask (e.g., dielectric) materials and/or other deposition processes may be used in other examples.

Referring to FIG. 10, the hardmask layer 902 and the pedestal dielectric layer 202b are etched to form a collector opening 1002 through the hardmask layer 902a and the pedestal dielectric layer 202c. The hardmask layer 902 and the pedestal dielectric layer 202b are etched through the opening 802 to form the collector opening 1002. The upper surface 120 of the semiconductor substrate 102 is exposed through the collector opening 1002. The collector opening 1002 generally extends from proximate to (or some lateral distance from) the first portion 122a of the isolation structure 122 laterally away from the first portion 122a of the isolation structure 122 in the BJT region 104.

In the illustrated example, the hardmask layer 902 and the pedestal dielectric layer 202b are patterned using appropriate photolithography and etch processes. An underlayer 1012 is formed over the hardmask layer 902. The underlayer 1012 may provide a planarized surface over which a photoresist is to be formed. The underlayer 1012 may be or include organic hardmask materials used in, e.g., a tri-layer patterning scheme or the like. The underlayer 1012 may be formed by using spin-on coating processes or the like. The underlayer 1012 may be planarized by a CMP in some examples. An anti-reflection coating (ARC) layer 1014 is formed over the underlayer 1012. The ARC layer 1014 may be or include inorganic hardmask materials used in, e.g., a tri-layer patterning scheme or the like. The ARC layer 1014 may be formed by using spin-on coating processes or the like. A photoresist 1016 is deposited (e.g., by spin-on) on or over the ARC layer 1014 and patterned using photolithography. The photoresist 1016 is patterned to have an opening 1018 (corresponding to the collector opening 1002) exposing the portion of the hardmask layer 902 that is to be removed. The opening 1018 is shown in the layout view in FIG. 41. With the patterned photoresist 1016, an etch process is performed, using the patterned photoresist 1016 as a mask, to remove portions of the hardmask layer 902 and pedestal dielectric layer 202b and to pattern the hardmask layer 902 and pedestal dielectric layer 202b into the hardmask layer 902a and pedestal dielectric layer 202c, respectively. The etch process may include a dry, anisotropic (e.g., plasma) etch, such as an RIE, followed by a wet etch. A plasma etch may be implemented to etch through the hardmask layer 902 and partially through the pedestal dielectric layer 202b, with the wet etch etching through the remainder of the pedestal dielectric layer 202b to the upper surface 120. Such etch process may avoid plasma damage to the crystalline structure of the upper surface 120 at the opening 1002. After the etch process, the photoresist 1016, ARC layer 1014, and underlayer 1012 are removed, such as by ashing and/or etching processes (e.g., wet etches) selective to materials of those layers. If ashing or a plasma process is performed to remove any of the photoresist 1016, ARC layer 1014, and underlayer 1012, a wet etch that etches through the remainder of the pedestal dielectric layer 202b may be performed after such ashing or plasma process.

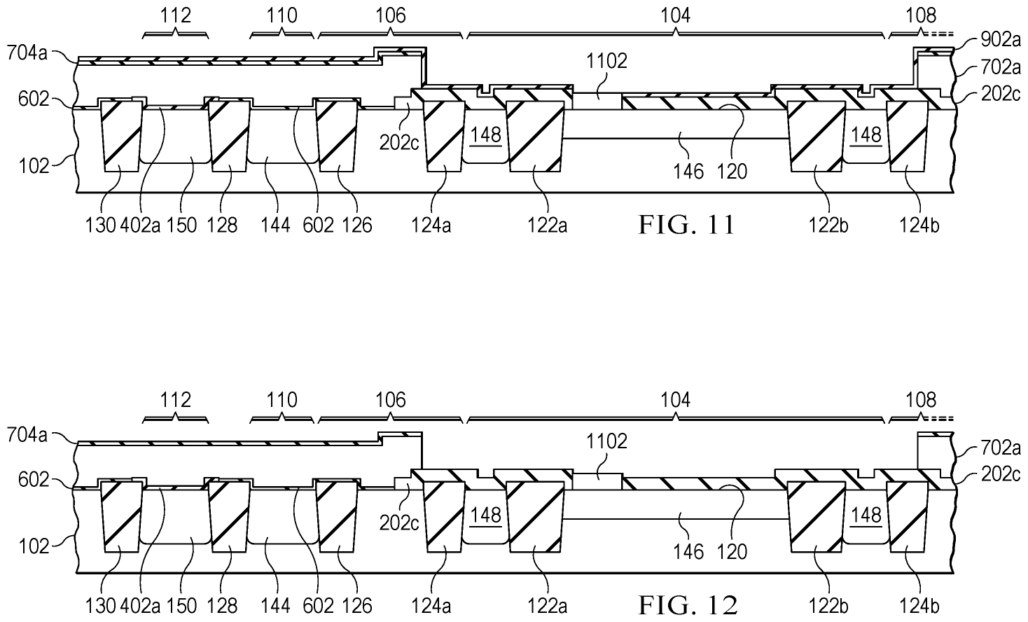

Referring to FIG. 11, a collector layer 1102 is formed over (e.g., on) the upper surface 120 of the semiconductor substrate 102 and in the collector opening 1002. In some examples, the collector layer 1102 is or includes a semiconductor layer doped with an n-type dopant (e.g., a same dopant type as the n-type doped sub-collector diffusion region 146). In some examples, the collector layer 1102 is or includes silicon. In some examples, the collector layer 1102 is doped with an n-type dopant with a concentration in a range from 1×10¹⁹ cm⁻³ to 1×10²¹ cm⁻³. The collector layer 1102 may be epitaxially grown on the upper surface 120 of the semiconductor substrate 102. The collector layer 1102 may be epitaxially grown by a selective epitaxial growth process in some examples. The epitaxial growth of the collector layer 1102 on the upper surface 120 of the semiconductor substrate 102 may result in the collector layer 1102 being monocrystalline. Further, the collector layer 1102 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

Referring to FIG. 12, the hardmask layer 902a is removed. The hardmask layer 902a may be removed using an etch selective to the material of the hardmask layer 902a, which may be a wet etch process. For example, when the hardmask layer 902a is silicon nitride, the hardmask layer 902a may be removed using a wet etch process that includes phosphoric acid (H₃PO₄).

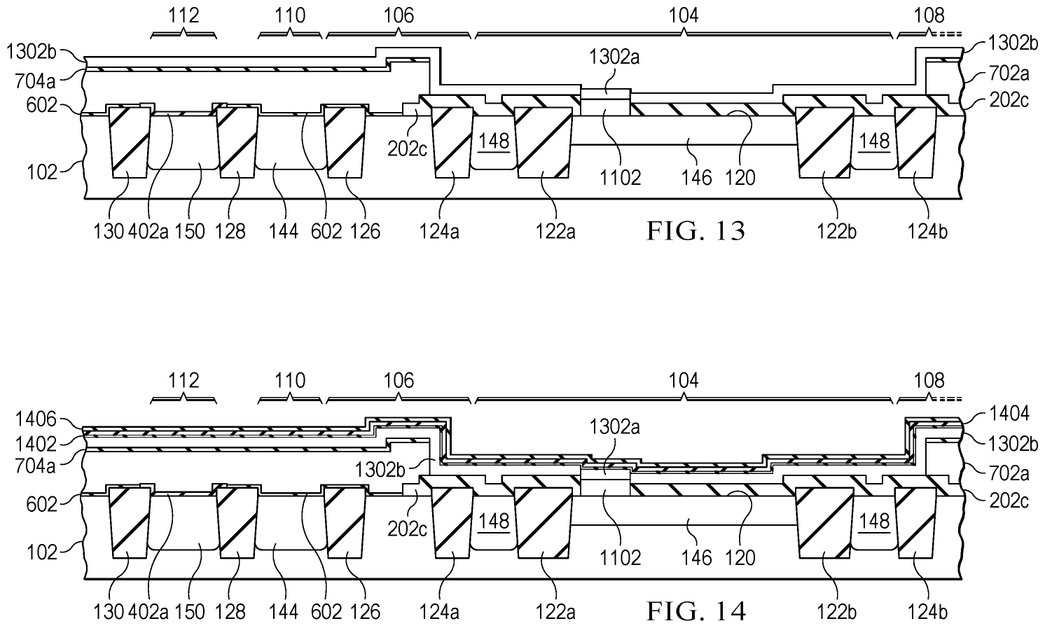

Referring to FIG. 13, a base layer 1302 is formed over the collector layer 1102. The base layer 1302 includes a monocrystalline base layer 1302a and a polycrystalline base layer 1302b. The monocrystalline base layer 1302a and polycrystalline base layer 1302b together form the base layer 1302. In some examples, the base layer 1302 is or includes a semiconductor layer doped with a p-type dopant (e.g., an opposite dopant type as the collector layer 1102). In some examples, the base layer 1302 is or includes silicon germanium. In some examples, the base layer 1302 is doped with a p-type dopant with a concentration in a range from 1×10¹⁷ cm⁻³ to 1×10²¹ cm⁻³. The base layer 1302 may also be doped with carbon (C) to prevent or reduce diffusion of the p-type dopant. The base layer 1302 may be epitaxially grown on the collector layer 1102, the pedestal dielectric layer 202c, the gate layer 702a, and the dielectric protective layer 704a. The base layer 1302 may be epitaxially grown by a non-selective epitaxial growth process in some examples. The non-selective epitaxial growth process grows the monocrystalline base layer 1302a from the collector layer 1102 and grows the polycrystalline base layer 1302b on other amorphous or polycrystalline surfaces, such as the pedestal dielectric layer 202c. The monocrystalline base layer 1302a may meet the polycrystalline base layer 1302b at a facet that is not specifically illustrated. The non-selective deposition of the base layer 1302 forms the base layer 1302 conformally in the opening 802 and on the dielectric protective layer 704a outside of the opening 802. The base layer 1302 may be in situ doped during the epitaxial growth process. The base layer 1302 (e.g., the monocrystalline base layer 1302a and polycrystalline base layer 1302b each) may further include multiple sub-layers, such as a nucleation sub-layer of the same material as the collector layer 1102, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

Referring to FIG. 14, a first dielectric spacer layer 1402 is formed conformally over the base layer 1302. A second dielectric spacer layer 1404 is formed conformally over the first dielectric spacer layer 1402, and a third dielectric spacer layer 1406 is formed conformally over the second dielectric spacer layer 1404. In some examples, the first dielectric spacer layer 1402 and third dielectric spacer layer 1406 are a same dielectric material, and the second dielectric spacer layer 1404 is a dielectric material different from the dielectric material of the first dielectric spacer layer 1402 and third dielectric spacer layer 1406. In some examples, the first dielectric spacer layer 1402 and third dielectric spacer layer 1406 are silicon oxide (e.g., a TEOS oxide), and the second dielectric spacer layer 1404 is silicon nitride. The dielectric spacer layers 1402-1406 may be deposited by CVD. Other dielectric materials and/or other deposition processes may be used in other examples.

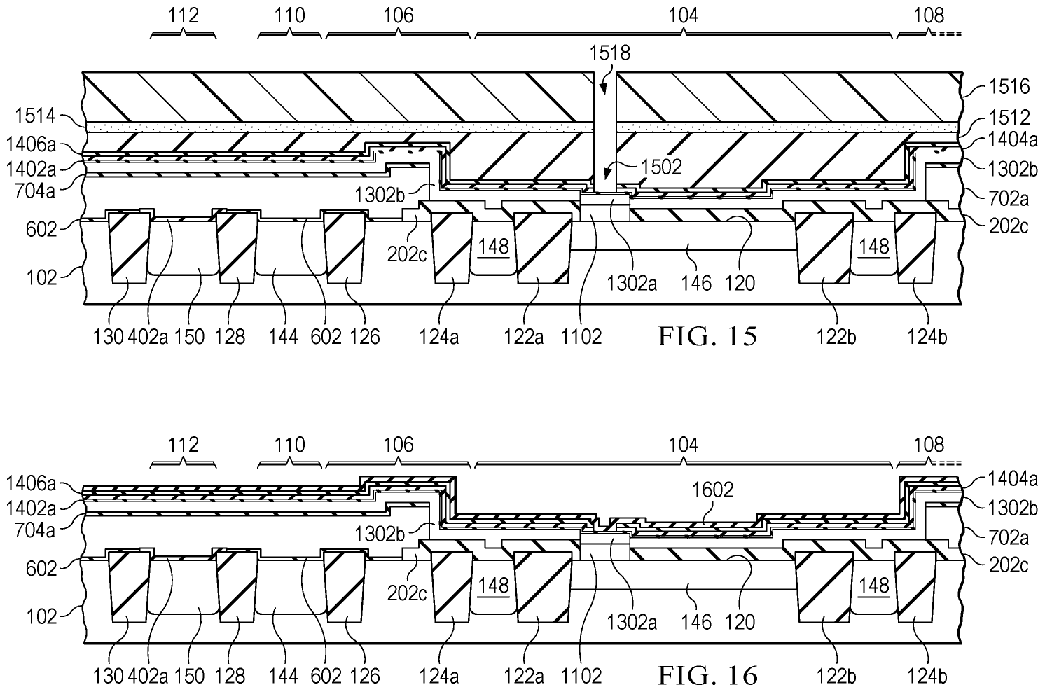

Referring to FIG. 15, the dielectric spacer layers 1402-1406 are etched to form a first emitter opening 1502 through the first dielectric spacer layer 1402a, second dielectric spacer layer 1404a, and third dielectric spacer layer 1406a. The dielectric spacer layers 1402-1406 are etched through the opening 802 to form the first emitter opening 1502. The monocrystalline base layer 1302a (of the base layer 1302) is exposed through the first emitter opening 1502. The first emitter opening 1502 is in the BJT region 104.

In the illustrated example, the dielectric spacer layers 1402-1406 are patterned using appropriate photolithography and etch processes. An underlayer 1512 is formed over the third dielectric spacer layer 1406. The underlayer 1512 may provide a planarized surface over which a photoresist is to be formed. An ARC layer 1514 is formed over the underlayer 1512. The underlayer 1512 and ARC layer 1514 may be formed like the underlayer 1012 and ARC layer 1014, respectively, described above with respect to FIG. 10. A photoresist 1516 is deposited (e.g., by spin-on) on or over the ARC layer 1514 and patterned using photolithography. The photoresist 1516 is patterned to have an opening 1518 (corresponding to the first emitter opening 1502) exposing the portion of the third dielectric spacer layer 1406 that is to be removed. The opening 1518 is shown in the layout view in FIG. 41. With the patterned photoresist 1516, an etch process is performed, using the patterned photoresist 1516 as a mask, to remove portions of the dielectric spacer layers 1402-1406 and to pattern the dielectric spacer layers 1402, 1404, 1406 into the dielectric spacer layers 1402a, 1404a, 1406a, respectively. The etch process may include a dry, anisotropic (e.g., plasma) etch, such as an RIE, followed by a wet etch. A plasma etch may be implemented to etch through the third dielectric spacer layer 1406 and the second dielectric spacer layer 1404, with the wet etch etching through the first dielectric spacer layer 1402 to the monocrystalline base layer 1302a. Such etch process may avoid plasma damage to the crystalline structure of the monocrystalline base layer 1302a at the opening 1502. After the etch process, the photoresist 1516, ARC layer 1514, and underlayer 1512 are removed, such as by ashing and/or etching processes (e.g., wet etches) selective to materials of those layers. If ashing or a plasma process is performed to remove any of the photoresist 1516, ARC layer 1514, and underlayer 1512, a wet etch that etches through the first dielectric spacer layer 1402 may be performed after such ashing or plasma process.

Referring to FIG. 16, an emitter dielectric spacer layer 1602 is conformally formed over the third dielectric spacer layer 1406a and in the first emitter opening 1502. In some examples, the emitter dielectric spacer layer 1602 is silicon oxide (e.g., a TEOS oxide) deposited by CVD, although other dielectric materials and/or other deposition processes may be used in other examples.

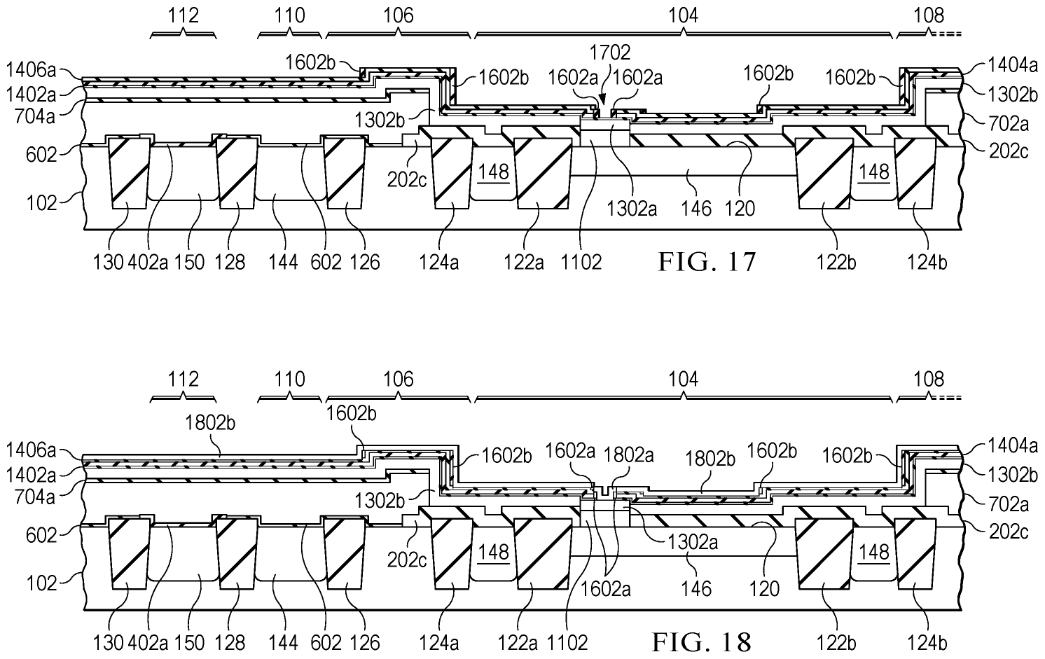

Referring to FIG. 17, the emitter dielectric spacer layer 1602 is anisotropically etched to form emitter dielectric spacers 1602a along sidewalls that define the first emitter opening 1502. The emitter dielectric spacers 1602a constrict the first emitter opening 1502 to form a second emitter opening 1702. Additionally, residual dielectric spacers 1602b remain on vertical surfaces of the third dielectric spacer layer 1406a. The anisotropic etch may be an RIE, for example.

Referring to FIG. 18, an emitter layer 1802 is formed over the base layer 1302 (e.g., on the monocrystalline base layer 1302a). The emitter layer 1802 includes a monocrystalline emitter layer 1802a and a polycrystalline emitter layer 1802b. The monocrystalline emitter layer 1802a and polycrystalline emitter layer 1802b together form the emitter layer 1802. In some examples, the emitter layer 1802 is or includes a semiconductor layer doped with an n-type dopant (e.g., an opposite dopant type from the base layer 1302). In some examples, the emitter layer 1802 is or includes silicon. In some examples, the emitter layer 1802 is doped with an n-type dopant with a concentration in a range from 1×10¹⁹ cm⁻³ to 1×10²¹ cm⁻³. The emitter layer 1802 may be epitaxially grown on the base layer 1302 (e.g., the monocrystalline base layer 1302a) exposed through the second emitter opening 1702, the emitter dielectric spacers 1602a, the residual dielectric spacers 1602b, and the third dielectric spacer layer 1406a. The emitter layer 1802 may be epitaxially grown by a non-selective epitaxial growth process in some examples. The non-selective epitaxial growth process grows the monocrystalline emitter layer 1802a from the monocrystalline base layer 1302a and grows the polycrystalline emitter layer 1802b on other amorphous or polycrystalline surfaces, such as the emitter dielectric spacers 1602a, the residual dielectric spacers 1602b, and the third dielectric spacer layer 1406a. The monocrystalline emitter layer 1802a may meet the polycrystalline emitter layer 1802b at a facet that is not specifically illustrated. The non-selective deposition of the emitter layer 1802 forms the emitter layer 1802 conformally in the opening 802 and on the third dielectric spacer layer 1406a and any residual dielectric spacer 1602b outside of the opening 802. The emitter layer 1802 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

Referring to FIG. 19, an emitter dielectric cap layer 1902 is conformally formed over the emitter layer 1802. In some examples, the emitter dielectric cap layer 1902 is silicon oxide (e.g., a TEOS oxide) deposited by CVD, although other dielectric materials and/or other deposition processes may be used in other examples.

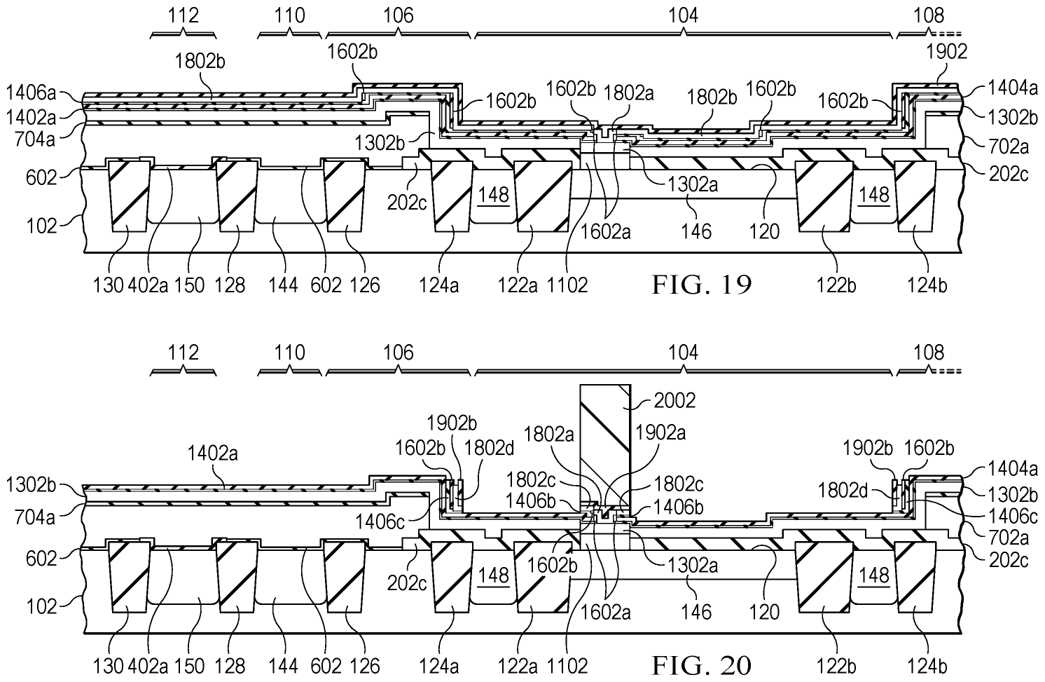

Referring to FIG. 20, the emitter dielectric cap layer 1902, polycrystalline emitter layer 1802b, and third dielectric spacer layer 1406a are etched to form the emitter dielectric cap layer 1902a, polycrystalline emitter layer 1802c, and third dielectric spacer 1406b in the opening 802. In the illustrated example, the layers 1902, 1802b, 1406a are patterned using appropriate photolithography and etch processes. A photoresist 2002 is deposited (e.g., by spin-on) on or over the emitter dielectric cap layer 1902 and patterned using photolithography. The photoresist 2002 is patterned to remain where the emitter layer 1802 is to be formed in the BJT. The patterned photoresist 2002 is shown in the layout view in FIG. 41. With the patterned photoresist 2002, an etch process, such as an anisotropic etch like an RIE or the like, is performed, using the patterned photoresist 2002 as a mask, to remove portions of the layers 1902, 1802b, 1406a and to pattern the emitter dielectric cap layer 1902, polycrystalline emitter layer 1802b, and third dielectric spacer layer 1406a into the emitter dielectric cap layer 1902a, polycrystalline emitter layer 1802c, and third dielectric spacer 1406b, respectively. After the etch process, the photoresist 2002 is removed, such as by ashing.

Anisotropically etching the emitter dielectric cap layer 1902, polycrystalline emitter layer 1802b, and third dielectric spacer layer 1406a may result in residual portions of those layers, e.g., at or near sidewalls 804, 806 of the opening 802 and within the opening 802. As illustrated, a residual emitter dielectric cap spacer 1902b, a residual polycrystalline emitter spacer 1802d, and a residual third dielectric spacer 1406c, along with a residual dielectric spacer 1602b, remain in the opening 802 and at or near the sidewall 804. Further, a residual emitter dielectric cap spacer 1902b, a residual polycrystalline emitter spacer 1802d, and a residual third dielectric spacer 1406c, along with a residual dielectric spacer 1602b, remain in the opening 802 and at or near the sidewall 806.

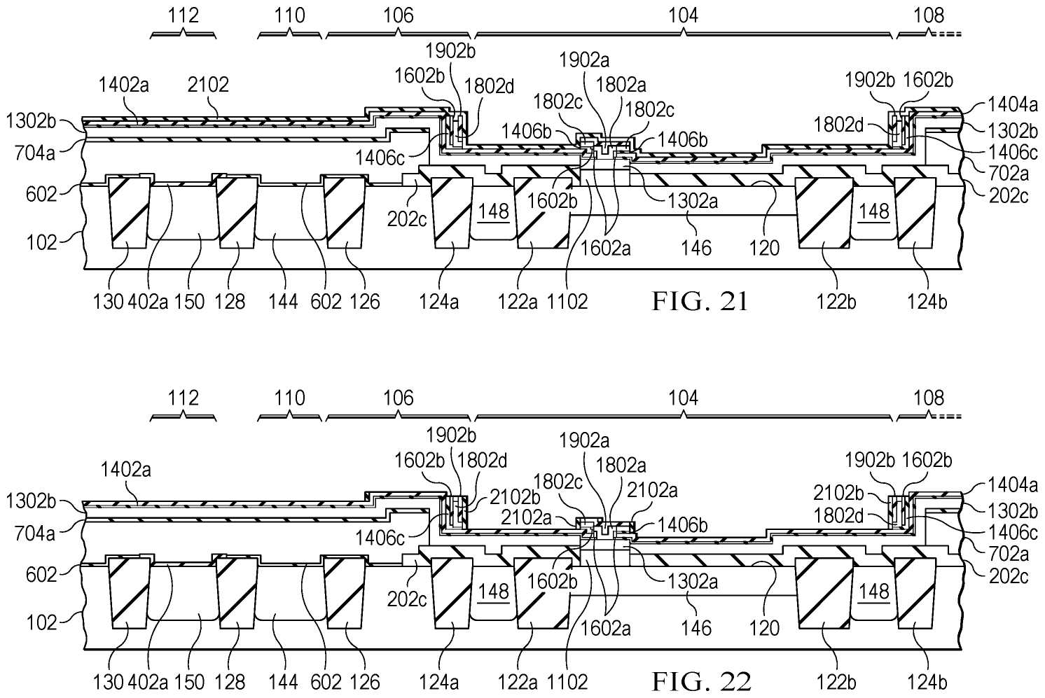

Referring to FIG. 21, an emitter dielectric protective spacer layer 2102 is conformally formed over the emitter dielectric cap layer 1902a and the second dielectric spacer layer 1404a and along sidewalls of the emitter dielectric cap layer 1902a, polycrystalline emitter layer 1802c, and third dielectric spacer 1406b. Additionally, the emitter dielectric protective spacer layer 2102 is conformally formed over the residual spacers 1406c, 1602b, 1802d, 1902b. In some examples, the emitter dielectric protective spacer layer 2102 is silicon oxide (e.g., a TEOS oxide) deposited by CVD, although other dielectric materials and/or other deposition processes may be used in other examples.

Referring to FIG. 22, the emitter dielectric protective spacer layer 2102 is anisotropically etched to form emitter dielectric protective spacers 2102a along sidewalls of the emitter dielectric cap layer 1902a, polycrystalline emitter layer 1802c, and third dielectric spacer 1406b. The emitter dielectric protective spacers 2102a protect sidewalls of the polycrystalline emitter layer 1802c. Additionally, residual dielectric spacers 2102b remain on vertical surfaces of the residual spacers 1902b, 1802d. The anisotropic etch may be an RIE, for example.

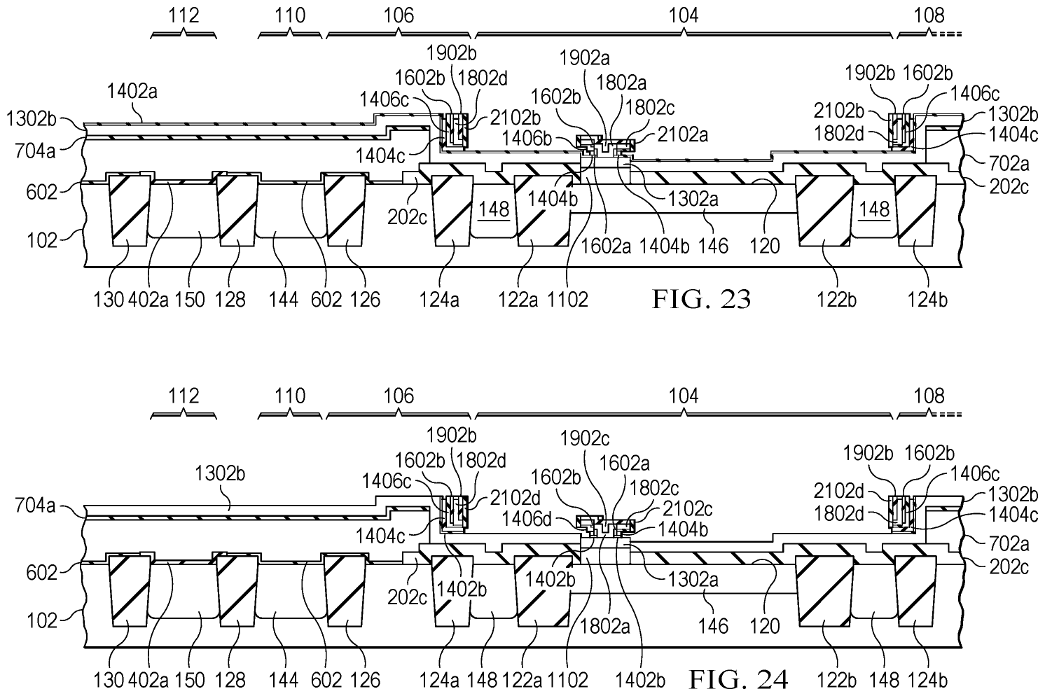

Referring to FIG. 23, the second dielectric spacer layer 1404a is etched. The etch removes exposed portions of the second dielectric spacer layer 1404a and undercuts the emitter dielectric protective spacers 2102a and third dielectric spacers 1406b laterally distal from the monocrystalline emitter layer 1802a, which results in second dielectric spacers 1404b under the third dielectric spacers 1406b. The etch may also undercut any of the residual spacers 2102b, 1902b, 1802d, 1602b, 1406c, which further forms residual second dielectric spacers 1404c. The etch may be a wet etch selective to the material of the second dielectric spacer layer 1404a. For example, when the second dielectric spacer layer 1404a is silicon nitride, the wet etch may include phosphoric acid.

Referring to FIG. 24, the first dielectric spacer layer 1402a is etched. Etching the first dielectric spacer layer 1402a generally removes the first dielectric spacer layer 1402a, such as from the monocrystalline base layer 1302a. A residual first dielectric spacer 1402b, as illustrated, remains under the residual second dielectric spacer 1404c. The etch may be a wet etch selective to the first dielectric spacer layer 1402a. For example, when the first dielectric spacer layer 1402a is silicon oxide, the first dielectric spacer layer 1402a may be removed using a dilute hydrochloric acid (dHCI) etch. A wet etch may remove the first dielectric spacer layer 1402a that underlies the emitter dielectric protective spacers 2102a and the second dielectric spacers 1404b. Additionally, the wet etch may further etch the emitter dielectric cap layer 1902a, emitter dielectric protective spacers 2102a, and the third dielectric spacers 1406b, which reduces a thickness of those layers and spacers and results in emitter dielectric cap layer 1902c, emitter dielectric protective spacers 2102c, and third dielectric spacers 1406d when those layers and spacers are a same material as the first dielectric spacer layer 1402a, such as illustrated. The removal of the first dielectric spacer layer 1402a opens (e.g., exposes) an area on the base layer 1302 near the monocrystalline emitter layer 1802a on which a raised base layer may be formed.

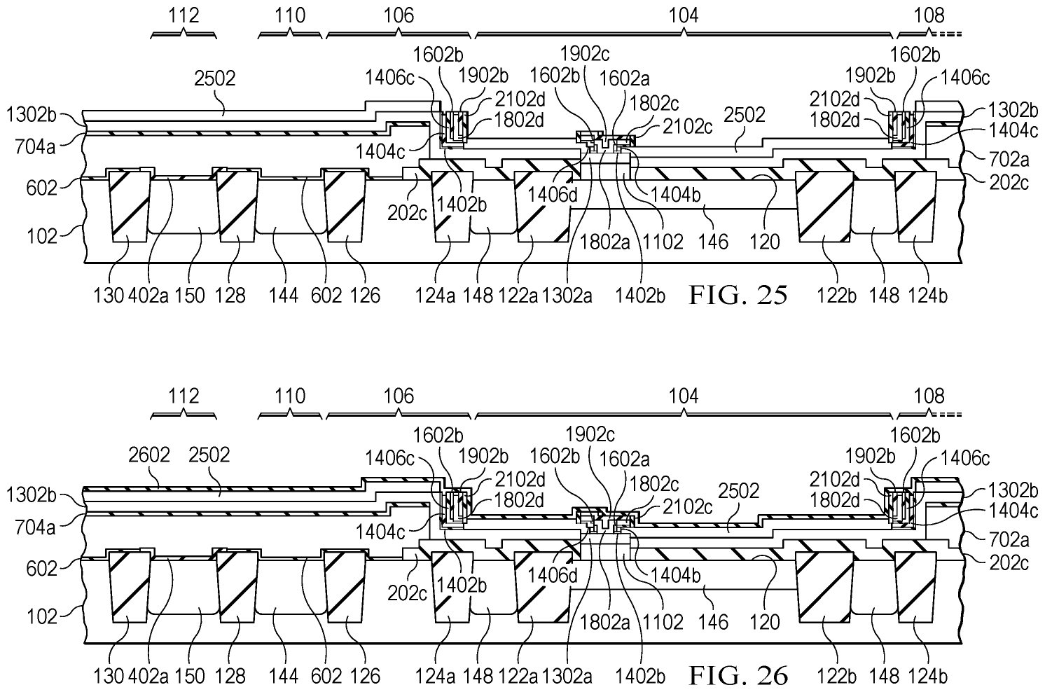

Referring to FIG. 25, a raised base layer 2502 is formed over the base layer 1302. The raised base layer 2502 includes at least a polycrystalline raised base layer on the polycrystalline base layer 1302b. The raised base layer 2502 may include a monocrystalline raised base layer. If the monocrystalline base layer 1302a is exposed by etching the first dielectric spacer layer 1402a, the raised base layer 2502 may include a monocrystalline portion on the monocrystalline base layer 1302a. In some examples, the raised base layer 2502 is or includes a semiconductor layer doped with a p-type dopant (e.g., a same dopant type as the base layer 1302). In some examples, the raised base layer 2502 is or includes silicon. In some examples, the raised base layer 2502 is doped with a p-type dopant with a concentration in a range from 1×10¹⁹ cm⁻³ to 1×10²¹ cm⁻³. The raised base layer 2502 may be epitaxially grown on the base layer 1302. The raised base layer 2502 may be epitaxially grown by a selective epitaxial growth process in some examples. The selective deposition of the raised base layer 2502 forms the raised base layer 2502 conformally on crystalline (e.g., polycrystalline and monocrystalline) surfaces in and outside of the opening 802 (e.g., on the base layer 1302). Further, the raised base layer 2502 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

Referring to FIG. 26, a dielectric protective layer 2602 is conformally formed over and along the emitter dielectric cap layer 1902c, the emitter dielectric protective spacers 2102c, and the raised base layer 2502. The dielectric protective layer 2602 is further conformally formed over and along the residual spacers 2102d, 1402b, 1404c, 1406c, 1902b, 1802d, 1602b. In some examples, the dielectric protective layer 2602 is silicon oxide (e.g., a TEOS oxide) deposited by CVD, although other dielectric materials and/or other deposition processes may be used in other examples.

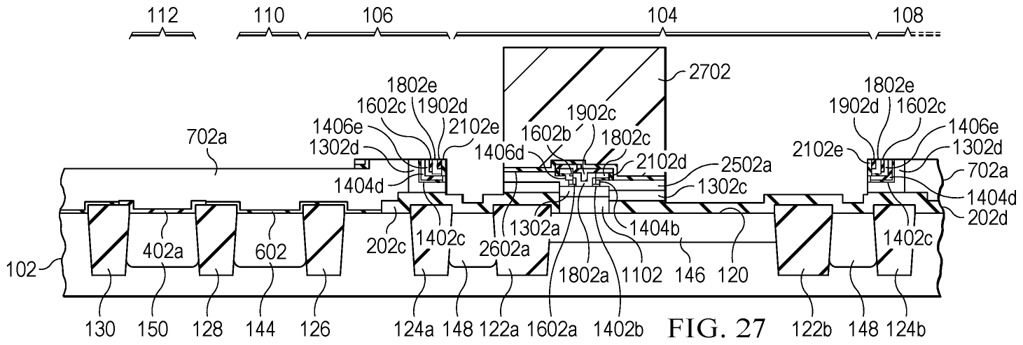

Referring to FIG. 27, the dielectric protective layer 2602, the raised base layer 2502, and the base layer 1302 (e.g., the polycrystalline base layer 1302b) are patterned. The raised base layer 2502 and the polycrystalline base layer 1302b are patterned to remain as the raised base layer 2502a and polycrystalline base layer 1302c within the opening 802. In the illustrated example, the layers 2602, 2502, 1302b are patterned using appropriate photolithography and etch processes. A photoresist 2702 is deposited (e.g., by spin-on) on or over the dielectric protective layer 2602 and patterned using photolithography. The photoresist 2702 is patterned to remain where the base layer 1302 is to be formed in the BJT. The patterned photoresist 2702 is shown in the layout view in FIG. 41. With the patterned photoresist 2702, an etch process, such as an anisotropic etch like an RIE or the like, is performed, using the patterned photoresist 2702 as a mask, to remove portions of the dielectric protective layer 2602, the raised base layer 2502, and the base layer 1302 and to pattern the dielectric protective layer 2602, the raised base layer 2502, and the polycrystalline base layer 1302b into the dielectric protective layer 2602a, the raised base layer 2502a, and the polycrystalline base layer 1302c, respectively. After the etch process, the photoresist 2702 is removed, such as by ashing. Patterning the base layer 1302 (e.g., the polycrystalline base layer 1302b) as illustrated permits residual polycrystalline base spacer 1302d to remain on respective sidewalls 804, 806. The etch process may further reduce exposed portions of the pedestal dielectric layer 202c, resulting in the pedestal dielectric layer 202d, and may remove the dielectric protective layer 704a. The etch process may also etch (e.g., reduce) residual spacers at the sidewalls 804, 806 of the opening 802. The etching of residual spacers results in residual spacers 1402c, 1404d, 1406e, 1602c, 1802e, 1902d, 2102e at respective sidewalls 804, 806.

In subsequent processing for forming the nFET and the pFET, a lower thermal budget may be implemented. The lower thermal budget may mitigate against relaxation of the monocrystalline base layer 1302a when the monocrystalline base layer 1302a is a material dissimilar from the collector layer 1102. The lower thermal budget may also mitigate against diffusion of dopants between the collector layer 1102, base layer 1302, and/or emitter layer 1802. Examples of such thermal processing with a lower thermal budget are provided below.

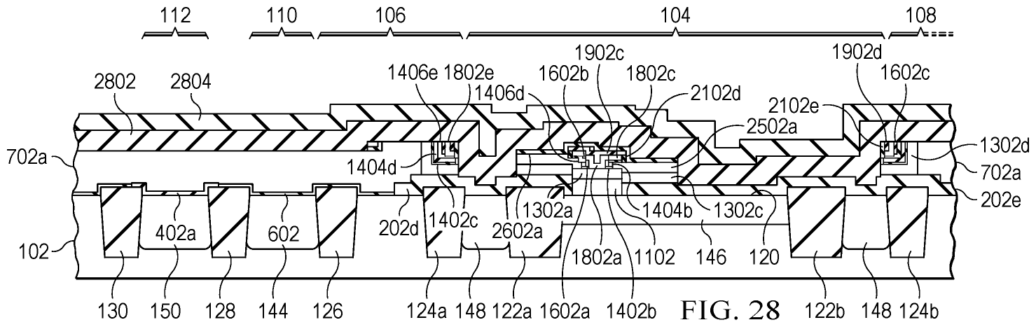

Referring to FIG. 28, a first hardmask layer 2802 is conformally formed over the gate layer 702a and in the opening 802, and a second hardmask layer 2804 is conformally formed over the first hardmask layer 2802. In some examples, the first hardmask layer 2802 is or includes silicon nitride deposited by CVD, although other hardmask (e.g., dielectric) materials and/or other deposition processes may be used in other examples. In some examples, the second hardmask layer 2804 is or includes silicon oxide deposited by CVD, although other hardmask (e.g., dielectric) materials and/or other deposition processes may be used in other examples.

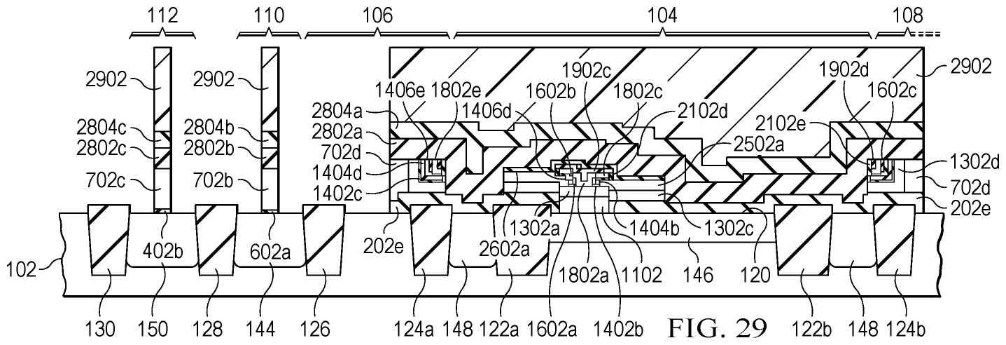

Referring to FIG. 29, the gate layer 702a is patterned into gate electrodes 702b, 702c, and the gate dielectric layers 402a, 602 are patterned into gate dielectric layers 402b, 602a, respectively. The first hardmask layer 2802 and second hardmask layer 2804 are patterned to a first hardmask layer 2802a and a second hardmask layer 2804a in the BJT region 104 and extending into the transition regions 106, 108. The first hardmask layer 2802 and second hardmask layer 2804 are patterned to first hardmask layers 2802b, 2802c and second hardmask layers 2804b, 2804c corresponding to the pattern of the gate electrodes 702b, 702c in the pFET region 110 and nFET region 112. In the illustrated example, the first hardmask layer 2802 and second hardmask layer 2804 are patterned using appropriate photolithography and etch processes. A photoresist 2902 is deposited (e.g., by spin-on) on or over the second hardmask layer 2804 and patterned using photolithography. The photoresist 2902 is patterned to remain where the first hardmask layer 2802 and/or second hardmask layer 2804 is to remain. The patterned photoresist 2902 in the BJT region 104 and transition regions 106, 108 is shown in the layout view in FIG. 41. With the patterned photoresist 2902, an etch process, such as an anisotropic etch like an RIE or the like, is performed, using the patterned photoresist 2902 as a mask, to remove portions of the first hardmask layer 2802 and second hardmask layer 2804 and to pattern the first hardmask layer 2802 and second hardmask layer 2804 into the first hardmask layer 2802a, 2802b, 2802c and second hardmask layer 2804a, 2804b, 2804c, respectively. After the etch process, the photoresist 2902 is removed, such as by ashing. Patterning the first hardmask layer 2802a, 2802b, 2802c and second hardmask layer 2804a, 2804b, 2804c may be a multi-patterning technique, even though one photoresist 2902 is shown.

Using the patterned first hardmask layers 2802a-2802c and second hardmask layers 2804a-2804c as a mask, the gate layer 702a and the gate dielectric layers 402a, 602 are patterned. Patterning the gate layer 702a also results in residual gate layer 702d in the transition regions 106, 108 and etching the pedestal dielectric layer 202d in the transition regions 106, 108 (resulting in pedestal dielectric layer 202e). The gate layer 702a and the gate dielectric layers 402a, 602 may be patterned using an appropriate etching process. For example, an anisotropic etch, such as an RIE, may be implemented. The gate electrode 702b is over (e.g., on) the gate dielectric layer 602a in the pFET region 110, and the gate electrode 702c is over (e.g., on) the gate dielectric layer 402b in the nFET region 112.

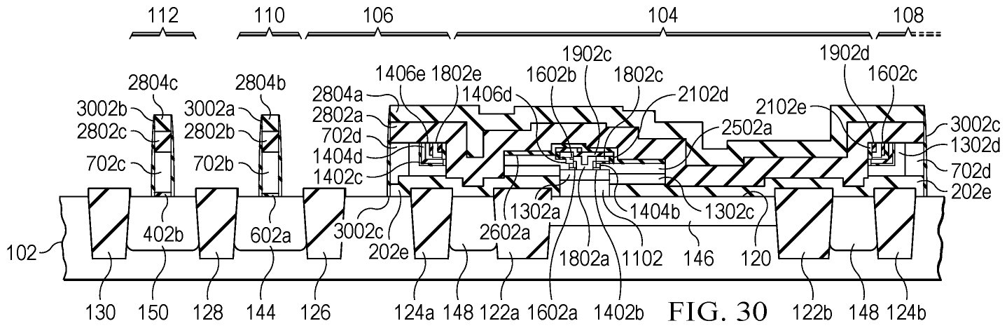

Referring to FIG. 30, protective dielectric layers 3002a, 3002b are formed along sidewalls of the gate electrodes 702b, 702c. The protective dielectric layers 3002a, 3002b may be formed by oxidizing sidewalls of the gate electrodes 702b, 702c, such as by ISSG oxidation. In some examples with a lower thermal budget, the oxidation process may be performed at 750° C. or less for 5 seconds or less. The formation of the protective dielectric layers 3002a, 3002b may further form residual protective dielectric layers 3002c, e.g., on sidewalls of the residual gate layer 702d. Other processes to form a protective dielectric layer (e.g., by deposition) may be implemented.

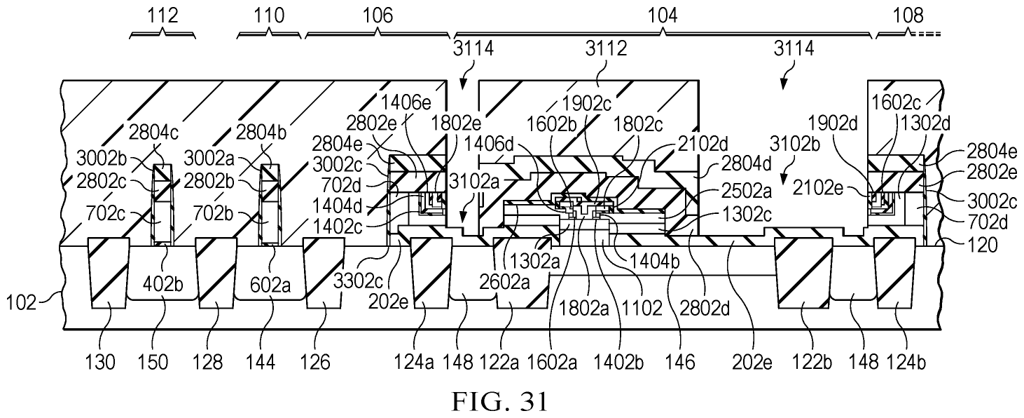

Referring to FIG. 31, the first hardmask layer 2802a and second hardmask layer 2804a are patterned to have an opening 3102 therethrough in the BJT region 104 and exposing the pedestal dielectric layer 202e. The opening 3102 laterally encompasses and is disposed laterally from the polycrystalline base layer 1302c. In the cross-section of FIG. 31, the opening 3102 has a first portion 3102a and a second portion 3102b. The first portion 3102a of the opening 3102 is at a boundary between the BJT region 104 and the first transition region 106. The second portion 3102b of the opening 3102 is in the BJT region 104 extending laterally from a boundary between the BJT region 104 and the second transition region 108. The first hardmask layer 2802a and second hardmask layer 2804a are patterned into first hardmask layer 2802d and second hardmask layer 2804d laterally encompassed by the opening 3102 and into first hardmask layer 2802e and second hardmask layer 2804e laterally outside of the opening 3102.

In the illustrated example, the hardmask layers 2802a, 2804a are patterned using appropriate photolithography and etch processes. A photoresist 3112 is deposited (e.g., by spin-on) on or over the second hardmask layers 2804a, 2804b, 2804c and patterned using photolithography. The photoresist 3112 is patterned with an opening 3114 corresponding to the opening 3102. The patterned photoresist 3112 that corresponds to patterning the pedestal dielectric layer 202e into the pedestal dielectric layer 202f (as described subsequently) is shown in the layout view in FIG. 41. With the patterned photoresist 3112, an etch process, such as an anisotropic etch like an RIE or the like, is performed, using the patterned photoresist 3112 as a mask, to remove portions of the hardmask layers 2802a, 2804a and to pattern the first hardmask layer 2802a into the first hardmask layers 2802d, 2802e and the second hardmask layer 2804a into the second hardmask layers 2804d, 2804e. After the etch process, the photoresist 3112 is removed, such as by ashing.

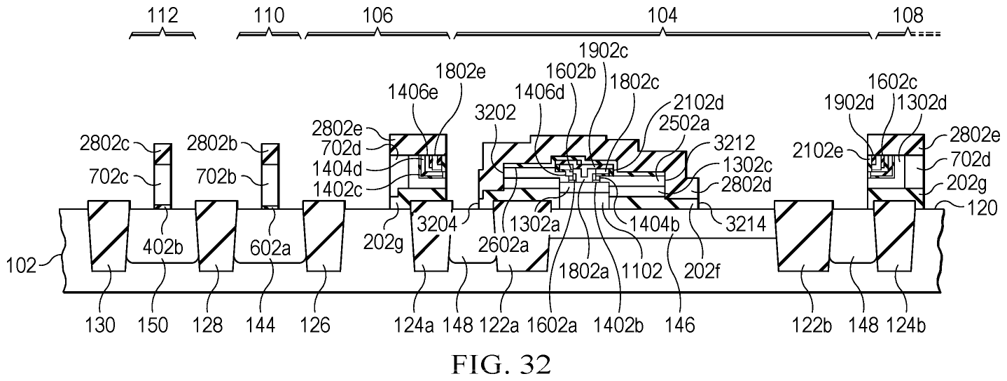

Referring to FIG. 32, the pedestal dielectric layer 202e is patterned into pedestal dielectric layer 202f and residual pedestal dielectric layer 202g, and the second hardmask layers 2804b, 2804c, 2804d, 2804e are removed. In some examples, the second hardmask layers 2804b, 2804c, 2804d, 2804e and the exposed portions of the pedestal dielectric layer 202e may be removed by a same etch, such as an etch (e.g., a wet etch) selective to the materials of the second hardmask layers 2804b, 2804c, 2804d, 2804e and the pedestal dielectric layer 202e. In such examples, the material of the second hardmask layers 2804b, 2804c, 2804d, 2804e and the material of the pedestal dielectric layer 202e may be a same material, such as a silicon oxide. In some examples, the second hardmask layers 2804b, 2804c, 2804d, 2804e and the exposed portions of the pedestal dielectric layer 202e may be removed by different etch processes. The removal of the second hardmask layers 2804b, 2804c, 2804d, 2804e and etching of the pedestal dielectric layer 202e may also remove the protective dielectric layers 3002d, 3002e, 3002f, such as illustrated.

As patterned, the pedestal dielectric layer 202f is over the semiconductor substrate 102 in the BJT region 104. The pedestal dielectric layer 202f extends laterally away from a sidewall 3202 of the base layer 1302 (e.g., the polycrystalline base layer 1302c) that is over the first portion 122a of the isolation structure 122. The pedestal dielectric layer 202f extends laterally away from the sidewall 3202 and to, and has a sidewall 3204 over, the upper surface 120 of the semiconductor substrate 102 between the first portion 122a of the isolation structure 122 and the first portion 124a of the isolation structure 124 (e.g., over the p-type doped well 148). The pedestal dielectric layer 202f also extends laterally away from another sidewall 3212 of the base layer 1302 (e.g., the polycrystalline base layer 1302c) that is over the n-type doped sub-collector diffusion region 146. The pedestal dielectric layer 202f extends laterally away from the sidewall 3212 and to, and has a sidewall 3214 over, the upper surface 120 of the semiconductor substrate 102 between the sidewall 3212 and the second portion 124b of the isolation structure 124 (e.g., over the n-type doped sub-collector diffusion region 146).

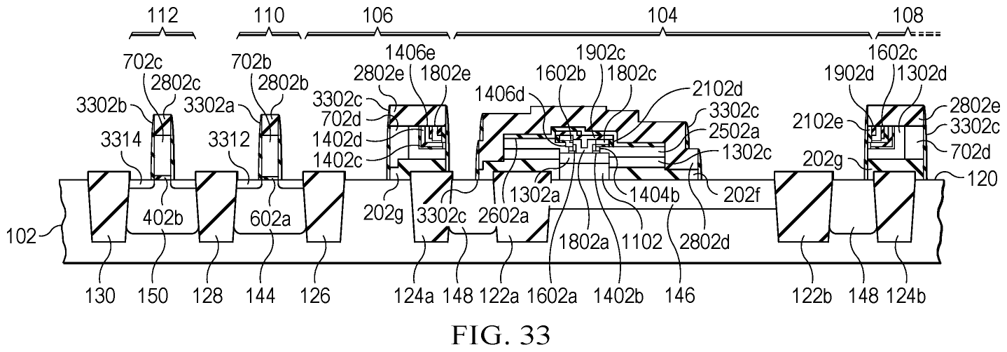

Referring to FIG. 33, first gate dielectric spacers 3302a, 3302b are formed along sidewalls of the gate electrodes 702b, 702c. The first gate dielectric spacers 3302a, 3302b may be formed by depositing a layer of the material of the first gate dielectric spacers 3302a, 3302b conformally over the semiconductor substrate 102 and anisotropically etching the layer such that the first gate dielectric spacers 3302a, 3302b remain. The material of the first gate dielectric spacers 3302a, 3302b may be any appropriate dielectric material, such as silicon nitride, silicon oxynitride, silicon carbon nitride, the like, or a combination thereof. The layer may be deposited by CVD, PECVD, atomic layer deposition (ALD), or the like. The formation of the first gate dielectric spacers 3302a, 3302b may further form residual dielectric spacers 3302c, e.g., on sidewalls of the residual gate layer 702d.

P-type lightly doped drain regions (LDDs) 3312 and n-type LDDs 3314 are formed in the semiconductor substrate 102 in the pFET region 110 and the nFET region 112, respectively. The p-type LDDs 3312 are in the semiconductor substrate 102 on laterally opposing sides of the gate electrode 702b, and the n-type LDDs 3314 are in the semiconductor substrate 102 on laterally opposing sides of the gate electrode 702c. The p-type LDDs 3312 may be formed by masking (e.g., by a photoresist using photolithography) the BJT region 104, transition regions 106, 108, and nFET region 112 and implanting a p-type dopant into the semiconductor substrate 102 in the pFET region 110. The n-type LDDs 3314 may be formed by masking (e.g., by a photoresist using photolithography) the BJT region 104, transition regions 106, 108, and pFET region 110 and implanting an n-type dopant into the semiconductor substrate 102 in the nFET region 112. A concentration of the p-type dopant of the p-type LDDs 3312 is greater than the concentration of the n-type dopant of the n-type doped well 144, and a concentration of the n-type dopant of the n-type LDDs 3314 is greater than the concentration of the p-type dopant of the p-type doped well 150. In some examples, the p-type LDDs 3312 are doped with a p-type dopant with a concentration in a range from 1×10¹⁹ cm⁻³ to 1×10²¹ cm⁻³, and the n-type LDDs 3314 are doped with an n-type dopant with a concentration in a range from 1×10¹⁹ cm⁻³ to 1×10²¹ cm⁻³. Other doping concentrations may be implemented.

After performing implantation(s) to form the p-type LDDs 3312 and the n-type LDDs 3314, an activation anneal may be performed. In some examples with a lower thermal budget, the activation anneal includes a laser anneal following the first implantation (e.g., of n-type or p-type dopants) and a spike anneal reaching 930° C. or less following the second implantation (e.g., of the other of the n-type or p-type dopants).

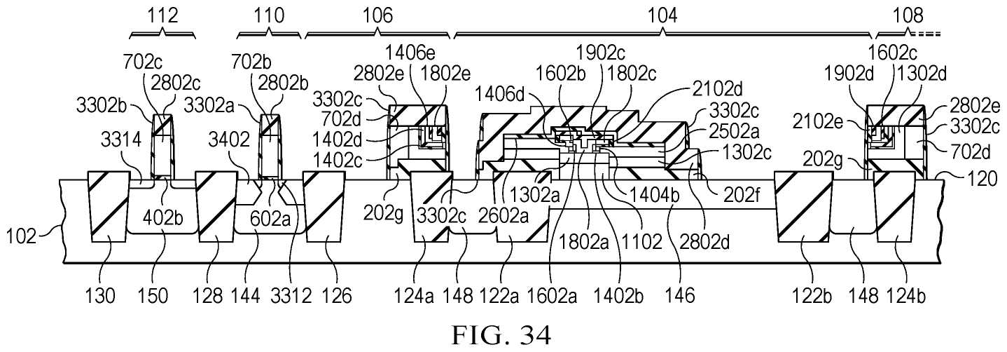

Referring to FIG. 34, embedded stressors 3402 are formed in the semiconductor substrate 102 in the pFET region 110. To form the embedded stressors 3402, respective recesses are formed in the semiconductor substrate 102. To form the recesses, a conformal hardmask layer is formed over the semiconductor substrate 102 in the BJT region 104, transition regions 106, 108, and nFET region 112. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching processes. Then, stressor recesses are formed in the semiconductor substrate 102 in the pFET region 110. The stressor recesses are etched in the semiconductor substrate 102 where the embedded stressors are to be formed. The stressor recesses may be formed using any appropriate etch process, which may be a wet or dry etch process. The etch process may be anisotropic and selective to (e.g., etching preferentially) a crystalline plane of the semiconductor substrate 102. The embedded stressors 3402 are then formed in the stressor recesses. The embedded stressors 3402 may be formed using a selective epitaxial growth process. The embedded stressors 3402 may be formed using MOCVD, molecular beam epitaxy (MBE), LPCVD, or another epitaxy process. After forming the embedded stressors 3402, the conformal hardmask layer is removed. The conformal hardmask layer may be removed by an etch process selective to the material of the conformal hardmask layer, which may be a wet or dry etch process. Removal of the conformal hardmask layer may also remove the first hardmask layers 2802b, 2802c, 2802d, 2802e, as illustrated in subsequent figures. For example, the conformal hardmask layer and the first hardmask layers 2802b, 2802c, 2802d, 2802e may be a same material that is removed by a same etch process. As an example, when the conformal hardmask layer and the first hardmask layers 2802b, 2802c, 2802d, 2802e are silicon nitride, a wet etch including phosphoric acid may remove the conformal hardmask layer and the first hardmask layers 2802b, 2802c, 2802d, 2802e.

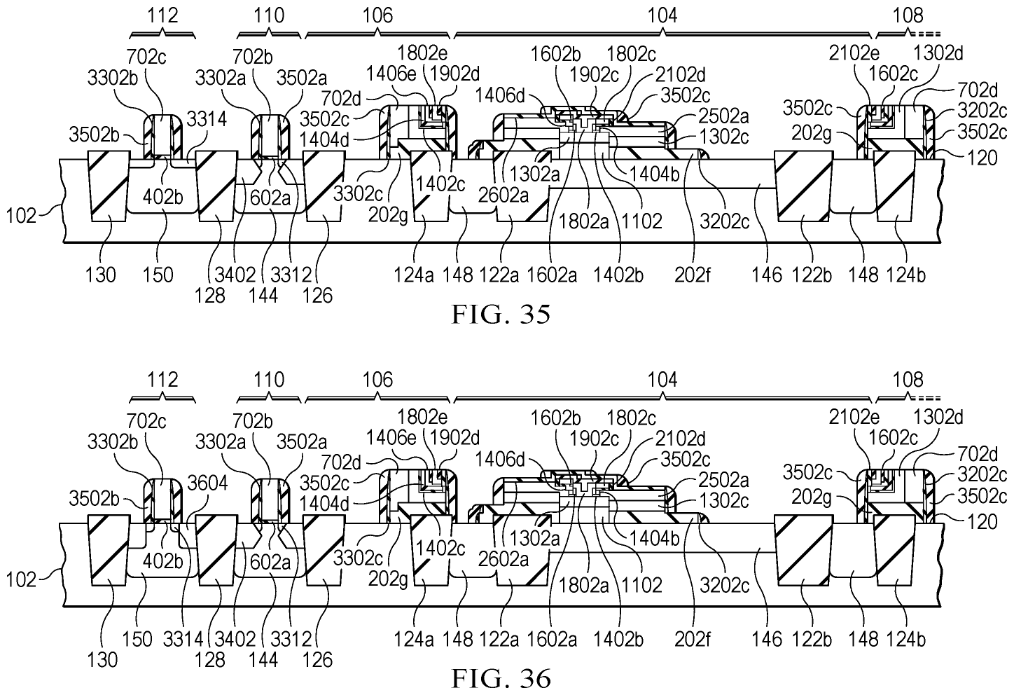

Referring to FIG. 35, second gate dielectric spacers 3502a, 3502b are formed along sidewalls of the first gate dielectric spacers 3302a, 3302b. The second gate dielectric spacers 3502a, 3502b may be formed by depositing a layer of the material of the second gate dielectric spacers 3502a, 3502b conformally over the semiconductor substrate 102 and anisotropically etching the layer such that the second gate dielectric spacers 3502a, 3502b remain. The material of the second gate dielectric spacers 3502a, 3502b may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers 3502a, 3502b may further form residual dielectric spacers 3502c on sidewalls of components in the BJT region 104 and transition regions 106, 108.

A stress memorization technique may be implemented, such as in the nFET region 112. A stressor dielectric layer is formed over the semiconductor substrate 102, gate electrode 702c, and gate dielectric spacers 3302b, 3502b in the nFET region 112. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 112. The anneal process may be or include a millisecond laser anneal for dopant activation and a spike rapid thermal anneal (RTA) with reduced thermal budget. A spike RTA may be at peak temperature for approximately 1 second and rapidly decrease in temperature to minimize dopant diffusion. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

Referring to FIG. 36, an n-type collector contact region 3602, n-type source/drain (NSD) regions 3604, and p-type source/drain (PSD) regions are formed in the semiconductor substrate 102. The n-type collector contact region 3602 is formed in the BJT region 104 in the n-type doped sub-collector diffusion region 146 in the semiconductor substrate 102. The n-type collector contact region 3602 is laterally between the pedestal dielectric layer 202f and the second portion 122b of the isolation structure 122. The NSD regions 3604 are formed in the nFET region 112 in the p-type doped well 150 in the semiconductor substrate 102. The NSD regions 3604 are on opposing lateral sides of the gate electrode 702c with the n-type LDDs 3314 therebetween. The PSD regions are formed in the pFET region 110 and may be formed in the embedded stressors 3402 and/or may further extend below the embedded stressors 3402 into the n-type doped well 144 in the semiconductor substrate 102. The PSD regions are on opposing lateral sides of the gate electrode 702b with the p-type LDDs 3312 therebetween.

An implantation is performed to form the n-type collector contact region 3602 and the NSD regions 3604. The n-type collector contact region 3602 and the NSD regions 3604 may be formed by masking (e.g., by a photoresist using photolithography) the pFET region 110 and the base layer 1302, raised base layer 2502a, and emitter layer 1802 in the BJT region 104 and implanting an n-type dopant into the semiconductor substrate 102 in the nFET region 112 and exposed portion of the BJT region 104. An implantation is performed to form the PSD regions. The PSD regions may be formed by masking (e.g., by a photoresist using photolithography) the BJT region 104 and the nFET region 112 and implanting a p-type dopant into the semiconductor substrate 102 in the pFET region 110. Simultaneously with implanting the PSD regions, the raised base layer 2502a and/or base layer 1302 may be implanted. The dielectric protective layer 2602a on the raised base layer 2502a may be exposed by the mask during the implantation of the PSD regions to also implant p-type dopant into the raised base layer 2502a and/or base layer 1302.

A concentration of the n-type dopant of the n-type collector contact region 3602 is greater than the concentration of the n-type dopant of the n-type doped sub-collector diffusion region 146. A concentration of the n-type dopant of the NSD regions 3604 is greater than the concentration of the n-type dopant of the n-type LDDs 3314 and the concentration of the p-type dopant of the p-type doped well 150. A concentration of the p-type dopant of the PSD regions is greater than the concentration of the p-type dopant of the p-type LDDs 3312 and the concentration of the n-type dopant of the n-type doped well 144. In some examples, the n-type collector contact region 3602 and the NSD regions 3604 are doped with an n-type dopant with a concentration in a range from 1×10²⁰ cm⁻³ to 1×10²¹ cm⁻³, and the PSD regions are doped with a p-type dopant with a concentration in a range from 1×10²⁰ cm⁻³ to 1×10²¹ cm⁻³. Other doping concentrations may be implemented.

After performing the implantations to form the n-type collector contact region 3602, NSD regions 3604, PSD regions, an activation anneal may be performed. In some examples with a lower thermal budget, the activation anneal includes a laser anneal following the first implantation (e.g., of n-type or p-type dopants) and a spike anneal reaching 1,010° C. or less following the second implantation (e.g., of the other of the n-type or p-type dopants).

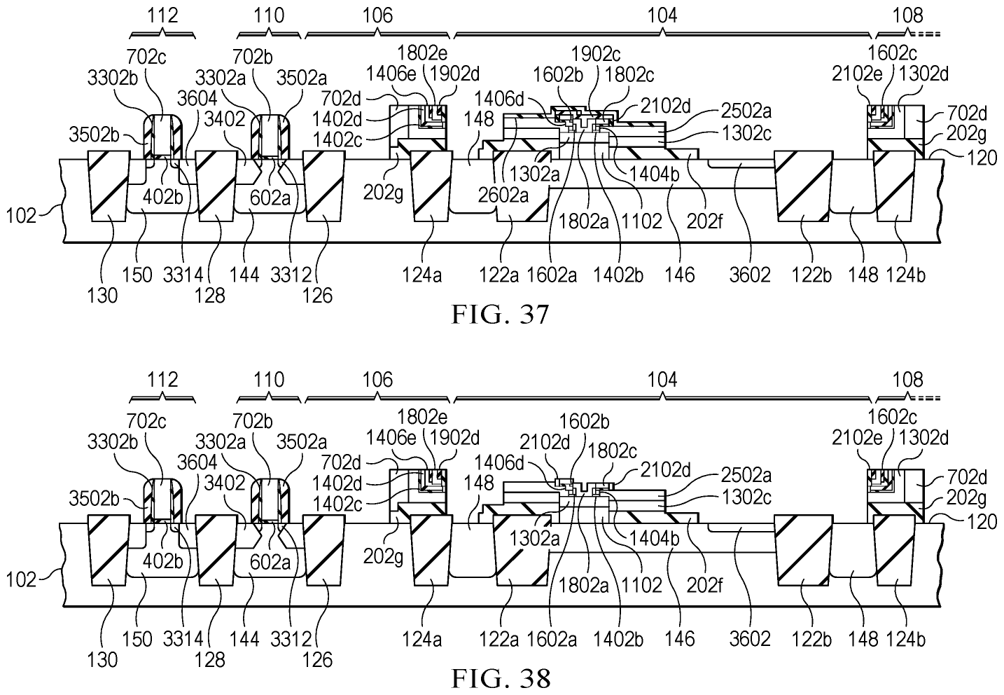

Referring to FIG. 37, residual dielectric spacers 3302c, 3502c may be removed. The residual dielectric spacers 3302c, 3502c may be removed by masking (e.g., by a photoresist using photolithography) the pFET region 110 and the nFET region 112 and performing an etch selective to the residual dielectric spacers 3302c, 3502c, which may be a wet or dry etch process.

Referring to FIG. 38, the dielectric protective layer 2602a and emitter dielectric cap layer 1902c are removed. The dielectric protective layer 2602a and the emitter dielectric cap layer 1902a may be removed by masking (e.g., by a photoresist using photolithography) remaining portions of the BJT region 104 and the transition regions 106, 108, pFET region 110, and nFET region 112 and performing an etch selective to the emitter dielectric cap layer 1902c. In some examples where the emitter dielectric cap layer 1902 and the emitter dielectric protective spacers 2102c are a same material, the removal of the emitter dielectric cap layer 1902a may also etch the emitter dielectric protective spacers 2102c to form emitter dielectric protective spacers 2102d.

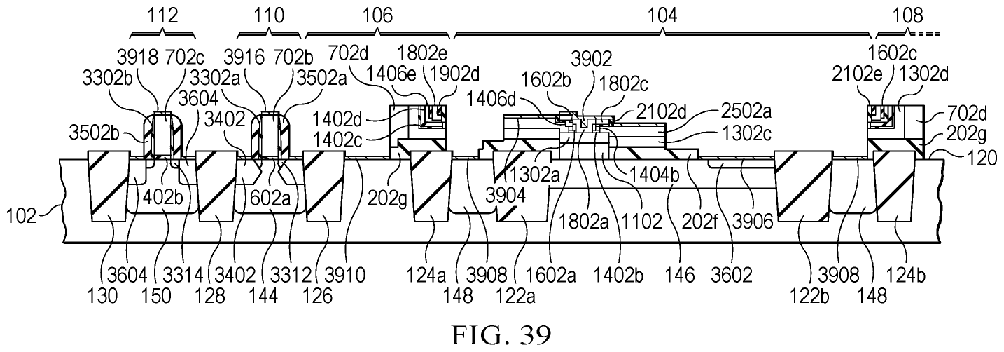

Referring to FIG. 39, metal-semiconductor compound 3902, 3904, 3906, 3908, 3910, 3912, 3914, 3916, 3918 are formed. The metal-semiconductor compound 3902 is on the emitter layer 1802 (e.g., the polycrystalline emitter layer 1802c and/or monocrystalline emitter layer 1802a). The metal-semiconductor compound 3904 is on the raised base layer 2502a. The metal-semiconductor compound 3906 is on the upper surface 120 of the semiconductor substrate 102 at the n-type collector contact region 3602. The metal-semiconductor compound 3908 is on the upper surface 120 of the semiconductor substrate 102 at the p-type doped well 148. The metal-semiconductor compound 3910 is on the upper surface 120 of the semiconductor substrate 102 in the first transition region 106. The metal-semiconductor compound 3912 are on the embedded stressors 3402. The metal-semiconductor compound 3914 are on the NSD regions 3604 in the semiconductor substrate 102. The metal-semiconductor compound 3916, 3918 are on the gate electrodes 702b, 702c, respectively. The metal-semiconductor compound 3902-3918 may be a silicide (e.g., NiSix, TiSix, CoSix, PtSix), a germanicide, or the like.

The metal-semiconductor compound 3902-3918 may be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 1802 (e.g., polycrystalline emitter layer 1802c and/or monocrystalline emitter layer 1802a), the semiconductor material of the raised base layer 2502a, the semiconductor material of the semiconductor substrate 102, the semiconductor material of the embedded stressors 3402, and the semiconductor material (e.g., silicon, such as polysilicon) of the gate electrodes 702b, 702c. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

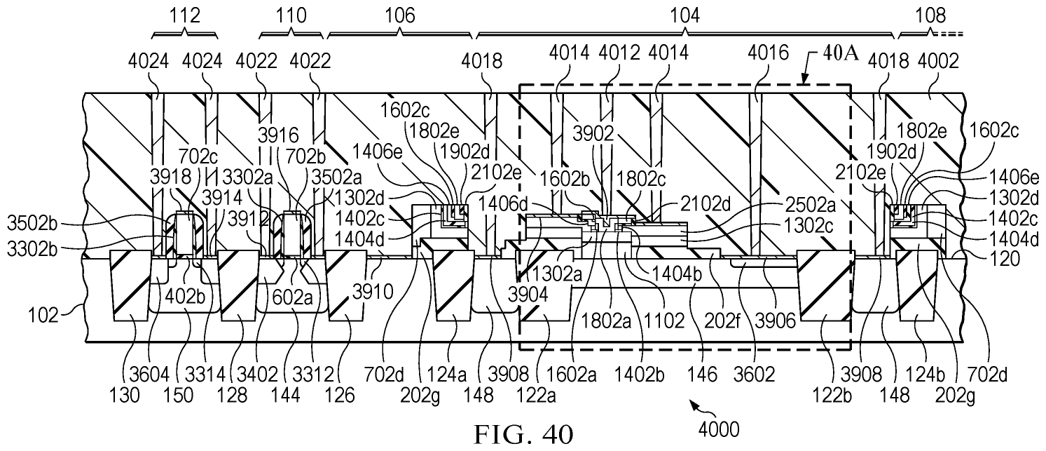

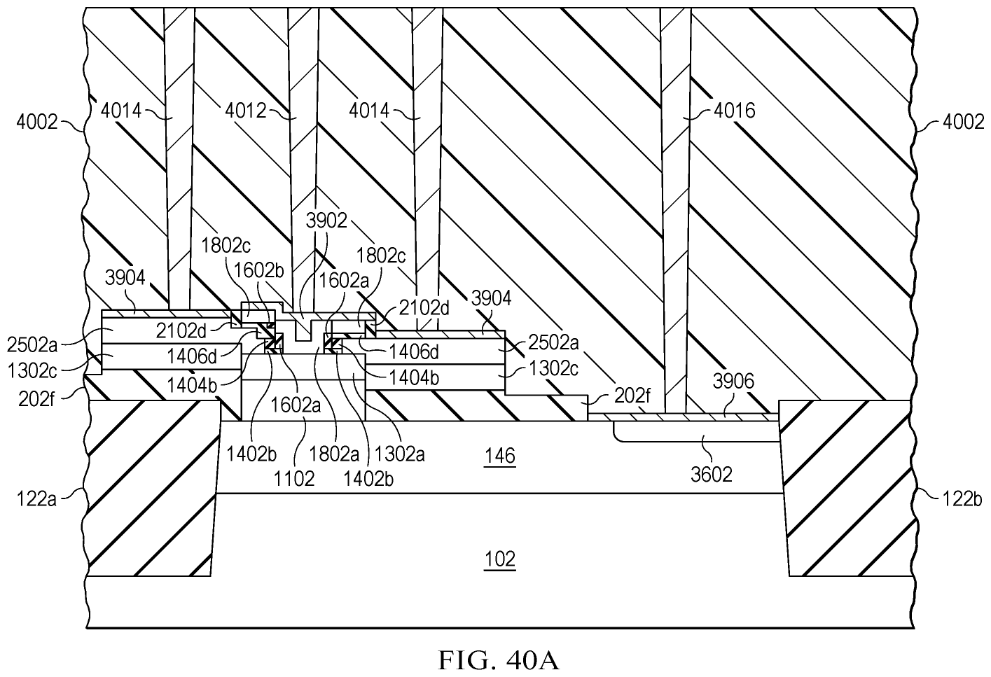

Referring to FIG. 40 and FIG. 40A (which shows a portion of FIG. 40 in enlarged detail), a dielectric layer 4002 is formed over the semiconductor substrate 102, and contacts 4012, 4014, 4016, 4018, 4022, 4024 are formed through the dielectric layer 4002. The dielectric layer 4002 may include one or more dielectric sub-layers. For example, the dielectric layer 4002 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 4002 may be or include a pre-metal dielectric (PMD), an inter-layer dielectric (ILD), or the like. The dielectric layer 4002 may be deposited using CVD, PECVD, ALD, or the like. The dielectric layer 4002 may be planarized, such as by a CMP.

The contacts 4012, 4014, 4016, 4018, 4022, 4024 extend through the dielectric layer 4002 and contact respective metal-semiconductor compound 3902, 3904, 3906, 3908, 3912, 3914. The contacts 4012, 4014, 4016, 4018, 4022, 4024 may each include one or more barrier and/or adhesion layers (e.g., titanium nitride (TiN), tantalum nitride (TaN), the like, or a combination thereof) conformally in a respective opening through the dielectric layer 4002, and a fill metal (e.g., tungsten (W), copper (Cu), aluminum (Al), the like, or a combination thereof) over and/or on the barrier and/or adhesion layer(s).

To form the contacts 4012, 4014, 4016, 4018, 4022, 4024, respective openings may be formed through the dielectric layer 4002 to the metal-semiconductor compound 3902, 3904, 3906, 3908, 3912, 3914 using appropriate photolithography and etching processes. A metal(s) of the contacts 4012, 4014, 4016, 4018, 4022, 4024 are deposited in the openings through the dielectric layer 4002. The metal(s) may be deposited using an appropriate deposition process(es), such as CVD, PVD, or the like. Any excess metal(s) may be removed, such as by a CMP and/or by patterning using photolithography and etch processes.

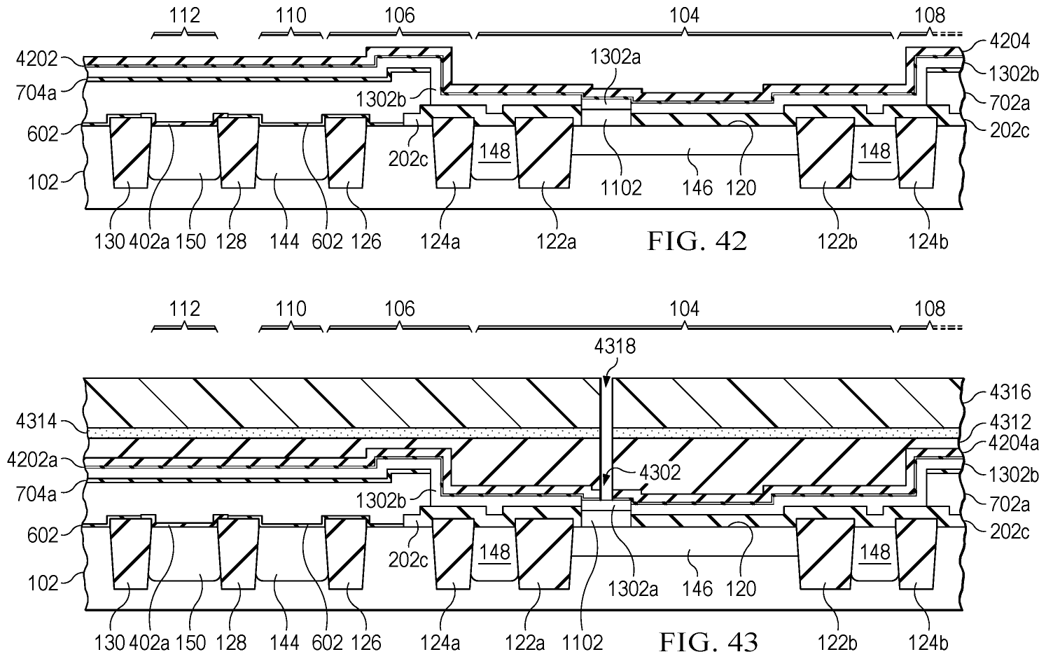

FIGS. 42 through 50 are respective cross-sectional views of a semiconductor device in intermediate stages of manufacturing according to some examples. Semiconductor processing proceeds as described above through FIG. 13.

With reference to FIG. 42, a first dielectric spacer layer 4202 is formed conformally over the base layer 1302, and a second dielectric spacer layer 4204 is formed conformally over the first dielectric spacer layer 4202. In some examples, the second dielectric spacer layer 4204 is a dielectric material different from the dielectric material of the first dielectric spacer layer 4202. In some examples, the first dielectric spacer layer 4202 is silicon oxide (e.g., a TEOS oxide), and the second dielectric spacer layer 4204 is silicon nitride. The dielectric spacer layers 4202, 4204 may be deposited by CVD. Other dielectric materials and/or other deposition processes may be used in other examples.

Referring to FIG. 43, the dielectric spacer layers 4202, 4204 are etched to form an emitter opening 4302 through the first dielectric spacer layer 4202a, and the second dielectric spacer layer 4204a. The dielectric spacer layers 4202, 4204 are etched through the opening 802 to form the emitter opening 4302. The monocrystalline base layer 1302a (of the base layer 1302) is exposed through the emitter opening 4302. The emitter opening 4302 is in the BJT region 104.

In the illustrated example, the dielectric spacer layers 4202, 4204 are patterned using appropriate photolithography and etch processes. An underlayer 4312 is formed over the second dielectric spacer layer 4204. An ARC layer 4314 is formed over the underlayer 4312. The underlayer 4312 and ARC layer 4314 may be formed like the underlayer 1512 and ARC layer 1514, respectively, described above with respect to FIG. 15. A photoresist 4316 is deposited (e.g., by spin-on) on or over the ARC layer 4314 and patterned using photolithography. The photoresist 4316 is patterned to have an opening 4318 (corresponding to the emitter opening 4302) exposing the portion of the second dielectric spacer layer 4204 that is to be removed. With the patterned photoresist 4316, an etch process is performed, using the patterned photoresist 4316 as a mask, to remove the exposed portion of the dielectric spacer layers 4202, 4204 and to pattern the dielectric spacer layers 4202, 4204 into the dielectric spacer layers 4202a, 4204a, respectively. The etch process may be like described above with respect to FIG. 15.

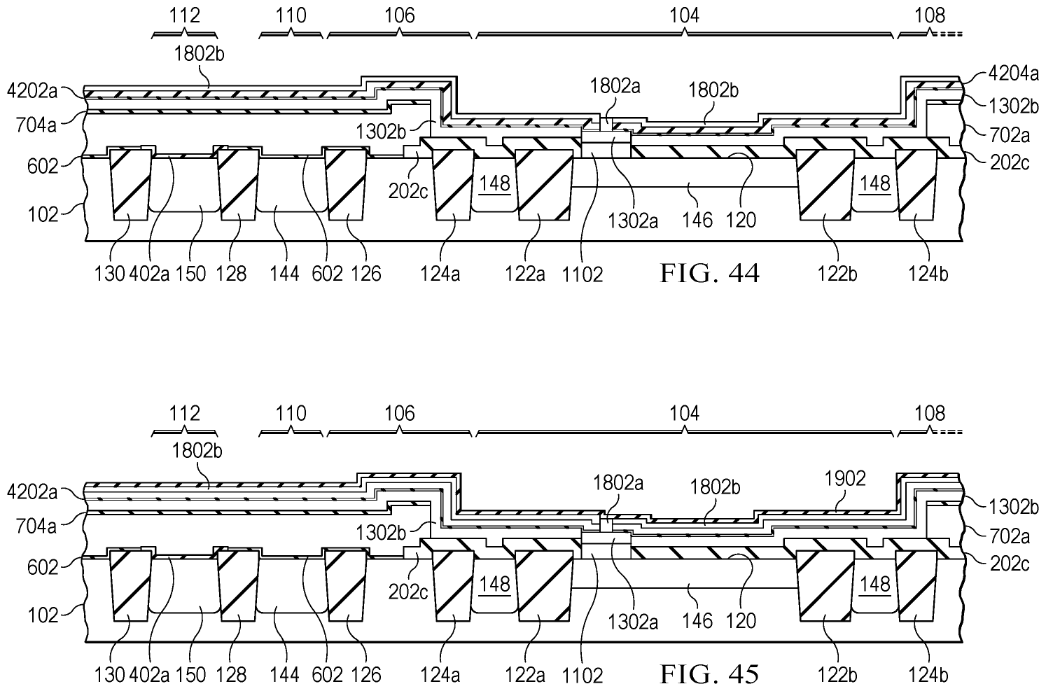

Referring to FIG. 44, an emitter layer 1802 is formed over the base layer 1302 (e.g., on the monocrystalline base layer 1302a) like described with respect to FIG. 18. The emitter layer 1802 may be epitaxially grown on the base layer 1302 (e.g., the monocrystalline base layer 1302a) exposed through the emitter opening 4302 and on the second dielectric spacer layer 4204a. Referring to FIG. 45, an emitter dielectric cap layer 1902 is conformally formed over the emitter layer 1802 like described with respect to FIG. 19.

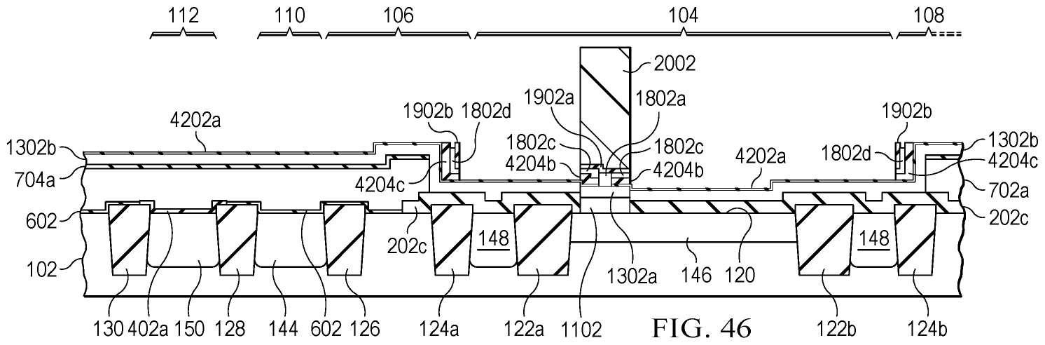

Referring to FIG. 46, the emitter dielectric cap layer 1902, the polycrystalline emitter layer 1802b, and the second dielectric spacer layer 4204a are etched to form the emitter dielectric cap layer 1902a, polycrystalline emitter layer 1802c, and second dielectric spacer 4204b in the opening 802. In the illustrated example, the layers 1902, 1802b, 4204a are patterned using appropriate photolithography and etch processes. A photoresist 2002 is deposited (e.g., by spin-on) on or over the emitter dielectric cap layer 1902 and patterned using photolithography. The photoresist 2002 is patterned to remain where the emitter layer 1802 is to be formed in the BJT. With the patterned photoresist 2002, an etch process, such as an anisotropic etch like an RIE or the like, is performed, using the patterned photoresist 2002 as a mask, to remove portions of the layers 1902, 1802b, 4204a and to pattern the emitter dielectric cap layer 1902, polycrystalline emitter layer 1802b, and second dielectric spacer layer 4204a into the emitter dielectric cap layer 1902a, polycrystalline emitter layer 1802c, and second dielectric spacer 4204b, respectively. After the etch process, the photoresist 2002 is removed, such as by ashing.

Anisotropically etching the emitter dielectric cap layer 1902, polycrystalline emitter layer 1802b, and second dielectric spacer layer 4204a may result in residual portions of those layers, e.g., at or near sidewalls 804, 806 of the opening 802 and within the opening 802. As illustrated, a residual emitter dielectric cap spacer 1902b, a residual polycrystalline emitter spacer 1802d, and a residual second dielectric spacer 4204c remain in the opening 802 and at or near the sidewall 804. Further, a residual emitter dielectric cap spacer 1902b, a residual polycrystalline emitter spacer 1802d, and a residual second dielectric spacer 4204c remain in the opening 802 and at or near the sidewall 806.

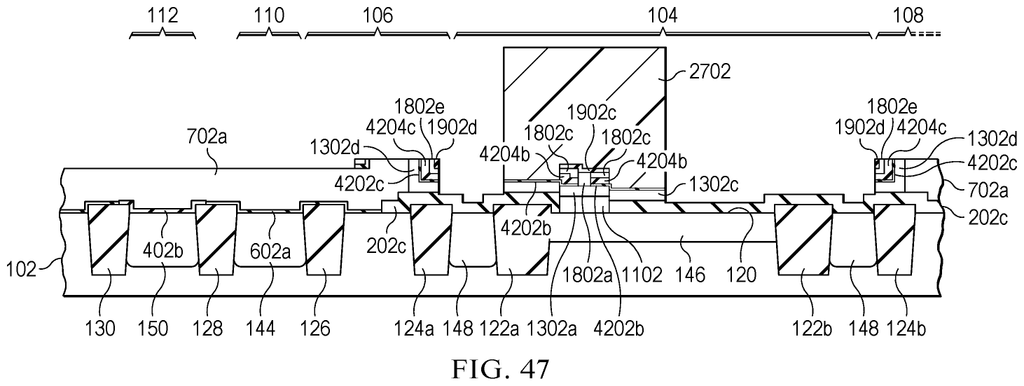

Referring to FIG. 47, the first dielectric spacer layer 4202a and the base layer 1302 (e.g., the polycrystalline base layer 1302b) are patterned. The first dielectric spacer layer 4202a is patterned to remain as the first dielectric spacer layer 4202b within the opening 802. The polycrystalline base layer 1302b is patterned to remain as the polycrystalline base layer 1302c within the opening 802. The first dielectric spacer layer 4202a and the base layer 1302 outside of the opening 802, and more specifically, outside of the BJT region 104, are removed by the patterning. In the illustrated example, the layers 1302b, 4202a are patterned using appropriate photolithography and etch processes. A photoresist 2702 is deposited (e.g., by spin-on) on or over the emitter dielectric cap layer 1902a and the first dielectric spacer layer 4202a and patterned using photolithography. The photoresist 2702 is patterned to remain where the base layer 1302 is to be formed in the BJT. With the patterned photoresist 2702, an etch process, such as an anisotropic etch like an RIE or the like, is performed, using the patterned photoresist 2702 as a mask, to remove portions of the first dielectric spacer layer 4202a and the base layer 1302 and to pattern the first dielectric spacer layer 4202a and the polycrystalline base layer 1302b into the first dielectric spacer layer 4202b and the polycrystalline base layer 1302c, respectively. After the etch process, the photoresist 2702 is removed, such as by ashing. Patterning the base layer 1302 (e.g., the polycrystalline base layer 1302b) as illustrated permits residual polycrystalline base spacer 1302d to remain on respective sidewalls 804, 806. The etch process may further reduce exposed portions of the pedestal dielectric layer 202c, resulting in the pedestal dielectric layer 202d, and may remove the dielectric protective layer 704a. The etch process may also etch (e.g., reduce) residual spacers at the sidewalls 804, 806 of the opening 802. The etching of residual spacers results in residual spacers 4202c, 4204c, 1802e, 1902b at respective sidewalls 804, 806.

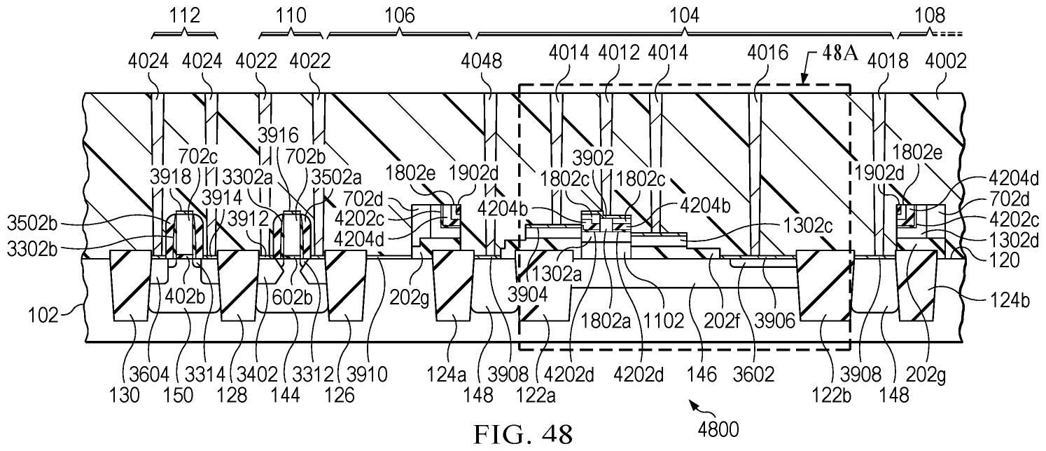

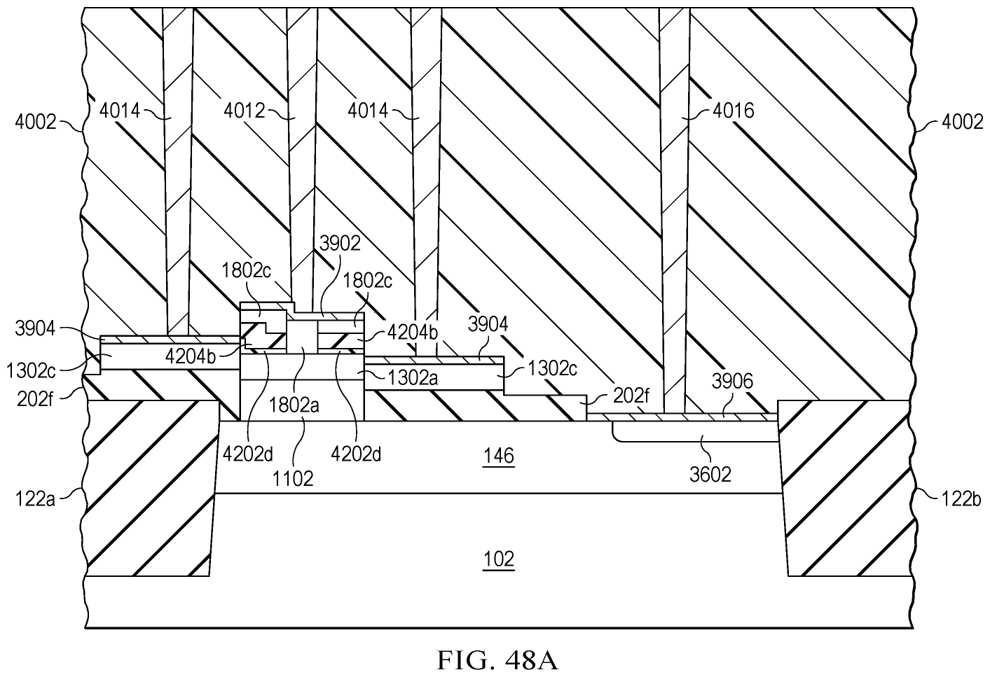

Referring to FIG. 48 and FIG. 48A (which shows a portion of FIG. 48 in enlarged detail), semiconductor processing continues as described with respect to FIGS. 28 through 40 above. With respect to the formation of metal-semiconductor compound described above with respect to FIG. 39, metal-semiconductor compound 3904 is on the base layer 1302 (e.g., the polycrystalline base layer 1302c). The deposited metal is reacted with the semiconductor material of the base layer 1302 (e.g., the polycrystalline base layer 1302c).

FIGS. 40 (and 40A) and 48 (and 48A) illustrate respective semiconductor devices 4000, 4800. Each illustrated semiconductor device 4000, 4800 includes a BJT in the BJT region 104. The BJT includes the collector layer 1102, base layer 1302 (e.g., monocrystalline base layer 1302a and polycrystalline base layer 1302c), and emitter layer 1802 (e.g., monocrystalline emitter layer 1802a and polycrystalline emitter layer 1802b). The BJT of the semiconductor device 4000 of FIG. 40 also includes a raised base layer 2502a on the base layer 1302 (e.g., on the polycrystalline base layer 1302c).

The collector layer 1102 is over and on the upper surface 120 of the semiconductor substrate 102 and is through an opening in a pedestal dielectric layer 202f, which is also over and on the upper surface of the semiconductor substrate 102. The collector layer 1102 is on the n-type doped sub-collector diffusion region 146 in the semiconductor substrate 102. The base layer 1302 (e.g., the monocrystalline base layer 1302a) is over and on the collector layer 1102, and the base layer 1302 (e.g., the polycrystalline base layer 1302c) is over and on an upper surface of the pedestal dielectric layer 202f. The pedestal dielectric layer 202f extends laterally from the base layer 1302, such as laterally over and along the upper surface 120 of the semiconductor substrate 102 in a lateral direction from the sidewall 3212 of the base layer 1302 to the sidewall 3214 of the pedestal dielectric layer 202f at the n-type collector contact region 3602.

The emitter layer 1802 (e.g., the monocrystalline emitter layer 1802a) is over and on the base layer 1302 (e.g., the monocrystalline base layer 1302a) and is through an opening defined by a spacer structure, and the emitter layer 1802 (e.g., the polycrystalline emitter layer 1802c) is over and on the spacer structure. In the semiconductor device 4000 of FIG. 40, the spacer structure includes the second dielectric spacer 1404b, the third dielectric spacer 1406d, and emitter dielectric spacer 1602a. In the semiconductor device 4800 of FIG. 48, the spacer structure includes the first dielectric spacer 4202d and the second dielectric spacer 4204b.

The metal-semiconductor compound 3902 is on the emitter layer 1802 (e.g., the polycrystalline emitter layer 1802c and/or monocrystalline emitter layer 1802a). The metal-semiconductor compound 3906 is on the upper surface 120 of the semiconductor substrate 102 on the n-type collector contact region 3602. In the semiconductor device 4000 of FIG. 40, the metal-semiconductor compound 3904 is on the raised base layer 2502a. In the semiconductor device 4800 of FIG. 48, the metal-semiconductor compound 3904 is on the base layer 1302 (e.g., the polycrystalline base layer 1302c).

In some examples, the BJT may be a heterojunction BJT. As indicated previously, in some examples, the collector layer 1102 and the emitter layer 1802 may be silicon, and the base layer 1302 may include silicon germanium. Hence, in some examples, the base layer 1302 may include a semiconductor material dissimilar from respective semiconductor materials of the collector layer 1102 and emitter layer 1802. The dissimilar semiconductor materials may form one or more heterojunctions in the BJT, and the BJT may therefore be a heterojunction BJT.

Each illustrated semiconductor device 4000, 4800 includes a pFET in the pFET region 110 and an nFET in the nFET region 112. The pFET region 110 and nFET region 112 are in a CFET region. The pFET includes the gate electrode 702b, gate dielectric layer 402b, embedded stressors 3402, PSD regions, p-type LDDs 3312, and a channel region in the semiconductor substrate 102 underlying the gate electrode 702b. The gate electrode 702b is over and on the gate dielectric layer 602a, and the gate dielectric layer 602a is over and on the upper surface 120 of the semiconductor substrate 102. The p-type LDDs 3312 are on laterally opposing sides of the gate electrode 702b and in the semiconductor substrate 102. The channel region is laterally between the p-type LDDs 3312. The embedded stressors 3402 and PSD regions are on laterally opposing sides of the gate electrode 702b, with the p-type LDDs 3312 and channel region therebetween. Similarly, the nFET includes the gate electrode 702c, gate dielectric layer 402b, NSD regions 3604, n-type LDDs 3314, and a channel region in the semiconductor substrate 102 underlying the gate electrode 702c. The gate electrode 702c is over and on the gate dielectric layer 402b, and the gate dielectric layer 402b is over and on the upper surface 120 of the semiconductor substrate 102. The n-type LDDs 3314 are on laterally opposing sides of the gate electrode 702c and in the semiconductor substrate 102. The channel region is laterally between the n-type LDDs 3314. The NSD regions 3604 are on laterally opposing sides of the gate electrode 702c, with the n-type LDDs 3314 and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The first transition region 106 is between the BJT region 104 and the CFET region (e.g., with the CFET region having a boundary of the pFET region 110 in the illustrated examples). The second transition region 108 extends from a boundary of the BJT region 104 (e.g., opposite from the first transition region 106). A composite structure may remain in the first transition region 106 and/or second transition region 108. The composite structure may be respective residuals of various layers formed during semiconductor processing and/or may be processing artifact(s). The composite structure includes the residual gate layer 702d, as shown in FIGS. 40 and 48. Further, the composite structure may include one or both of a residual polycrystalline base spacer 1302d and a residual polycrystalline emitter spacer 1802e. The composite structure may include one or more residual dielectric spacers, such as the residual dielectric spacers 1402c, 1404d, 1406e, 1602c, 1902d, 2102e as shown in FIG. 40 and the residual dielectric spacers 4202c, 4204c, 1902d as shown in FIG. 48. Other composite structures may be formed.

In the semiconductor processing to form the semiconductor devices 4000, 4800 of FIGS. 40 and 48, masks (e.g., photoresists) that are implemented may improve manufacturability and ease of processing. With reference to FIGS. 8 and 41, the photoresist 812 with the opening 814 that is implemented causes the gate layer 702 to be removed from the BJT region 104 (e.g., within the inner boundaries of the isolation structure 124). This results in a larger opening 802 through the gate layer 702a in which the BJT is formed, which may increase ease of processing. With reference to FIGS. 29 and 41, the photoresist 2902 in the BJT region 104 extending into the transition regions 106, 108 causes the residual gate layer 702d to remain in the transition regions 106, 108. As shown in FIG. 41, the overlap 4102 of the photoresists 812, 2902 results in the residual gate layer 702d being formed in the transition regions 106, 108. The residual gate layer 702d laterally encompasses the BJT region 104 (e.g., laterally outside of the p-type doped well 148). The residual gate layer 702d may create a fence laterally encompassing the BJT region 104 that may support residual layers or spacers (e.g., “stringers”) that may be created during processing along respective sidewalls 804, 806 of the gate layer 702a. This support may reduce a likelihood that residual layers or spacers lift off in subsequent processing, which may reduce defectivity during processing and increase yield of manufactured devices.

Patterning the pedestal dielectric layer 202e into the pedestal dielectric layer 202f later in processing (e.g., in FIG. 32) permits the patterning of the gate layer 702a with the opening 802 earlier in processing while maintaining protection of the upper surface 120 of the semiconductor substrate 102 in the BJT region 104. The pedestal dielectric layer 202b-202e remains over and protects the upper surface 120 of the semiconductor substrate 102 where the n-type collector contact region 3602 is to be formed during formation of the BJT (e.g., during the epitaxial growth of the base layer 1302 and emitter layer 1802). Additionally, patterning the pedestal dielectric layer 202e into the pedestal dielectric layer 202f in FIG. 32 may permit more freedom to choose how the pedestal dielectric layer 202f is to be patterned. In the described method, the pedestal dielectric layer 202f is patterned near the end of processing of the BJT. Hence, there may be reduced considerations or constraints for how the pedestal dielectric layer 202f is patterned. This may permit the pedestal dielectric layer 202f to be patterned in a way that loosens alignment specifications of photolithography processes when implanting dopants for the n-type collector contact region 3602, for example.

The semiconductor processing to form the semiconductor devices 4000, 4800 of FIGS. 40 and 48 may enable vertical scaling and horizontal scaling. In some examples, for vertical scaling, thicknesses of the collector layer 1102, base layer 1302, and emitter layer 1802 may be reduced. In some examples, a thickness of the collector layer 1102 does not exceed 200 nm, and a thickness of the base layer 1302 (e.g., the monocrystalline base layer 1302a) does not exceed 100 nm. Further, in some examples, the thickness of the collector layer 1102 is in a range from 10 nm to 100 nm, and a thickness of the base layer 1302 (e.g., the monocrystalline base layer 1302a) is in a range from 10 nm to 50 nm. Additionally, in some examples, a thickness of the emitter layer 1802 (e.g., the monocrystalline emitter layer 1802a) does not exceed 100 nm. In some examples, the thickness of the emitter layer 1802 (e.g., the monocrystalline emitter layer 1802a) is in a range from 10 nm to 50 nm. Generally, a thickness of a given layer is in a direction normal to a tangent plane of the underlying surface on which the given layer is formed. However, in some instances, such as with a conformal deposition, a direction normal to a tangent plane of the underlying surface may not be a thickness, such as where a thickness from another tangent plane intersects that direction normal, like at a corner.

For horizontal scaling, widths of respective openings in which the collector layer 1102 and the emitter layer 1802 (e.g., the monocrystalline emitter layer 1802a) are formed, may be reduced. The width of the collector opening 1002, in which the collector layer 1102 is formed, may be reduced, and the width of the emitter opening 1502, 4302, in which the monocrystalline emitter layer 1802a is formed, may be reduced. The semiconductor processing described above may enable horizontal scaling to, e.g., a 28 nm technology node and beyond (e.g., a 21 nm technology node or less). Referring to FIG. 41, the lateral boundaries of the pedestal dielectric layer 202f correspond to the pattern of the photoresist 3112. The collector layer 1102 is laterally interior within the pedestal dielectric layer 202f in the collector opening 1002, which corresponds to the opening 1018 shown in FIG. 41. The opening 1018 and hence, the collector layer 1102 (and further, the collector opening 1002) has a width 4112. The lateral boundaries of the base layer 1302 (e.g., the polycrystalline base layer 1302c), and where applicable, the raised base layer 2502a, correspond to the pattern of the photoresist 2702. The emitter opening 1502, 4302 shown in FIGS. 15 and 43 correspond to the opening 1518 in FIG. 41. The opening 1518 has a width 4114. The emitter layer 1802 (e.g., the monocrystalline emitter layer 1802a) is formed in the emitter opening 1502, 4302, which may be laterally reduced or constricted by dielectric spacers (e.g., emitter dielectric spacers 1602a). One or both of the widths 4112, 4114 may be reduced for horizontal scaling. In some examples, the width 4112 does not exceed 200 nm, and the width 4114 does not exceed 120 nm. Further, in some examples, the width 4112 is in a range from 80 nm to 180 nm, and the width 4114 is in a range from 40 nm to 100 nm.

Although various examples have been described in detail, it should be understood that various changes, substitutions, and alterations can be made therein without departing from the scope defined by the appended claims.

What is claimed is:

1. A semiconductor device, comprising:
a semiconductor substrate including a bipolar junction transistor (BJT) region, a complementary field effect transistor (CFET) region, and a transition region between the BJT region and the CFET region;
a BJT on the semiconductor substrate in the BJT region;
a field effect transistor (FET) on the semiconductor substrate in the CFET region; and
a composite structure on the semiconductor substrate in the transition region, the composite structure comprising a first material that is the same as a gate electrode of the FET.

2. The semiconductor device of claim 1, wherein:
the BJT comprises:
a collector layer on the semiconductor substrate;
a base layer on the collector layer; and
an emitter layer on the base layer; and
the composite structure further comprises a second material that is the same as the base layer.

3. The semiconductor device of claim 2, wherein the second material is on a sidewall of the first material.

4. The semiconductor device of claim 1, further comprising a pedestal dielectric layer on the semiconductor substrate in the BJT region, wherein the BJT comprises:
a collector layer in an opening through the pedestal dielectric layer;
a base layer on the collector layer and the pedestal dielectric layer; and
an emitter layer on the base layer.

5. The semiconductor device of claim 4, wherein the semiconductor substrate includes:
a doped sub-collector diffusion region in the BJT region, the collector layer being on the doped sub-collector diffusion region; and
a doped collector contact region in the doped sub-collector diffusion region, at least a portion of the pedestal dielectric layer being laterally between the collector layer and the doped collector contact region.

6. The semiconductor device of claim 4, wherein the pedestal dielectric layer extends laterally away from the base layer.

7. The semiconductor device of claim 4, wherein the BJT further comprises a raised base layer on the base layer.

8. The semiconductor device of claim 7, further comprising:
a base metal-semiconductor compound on the raised base layer; and
an emitter metal-semiconductor compound on the emitter layer.

9. The semiconductor device of claim 4, further comprising:
a base metal-semiconductor compound on the base layer; and
an emitter metal-semiconductor compound on the emitter layer.

10. The semiconductor device of claim 4, wherein:
a thickness of the collector layer does not exceed 200 nm; and
a thickness of the base layer does not exceed 100 nm.

11. The semiconductor device of claim 10, wherein:
the thickness of the collector layer is in a range from 10 nm to 100 nm; and
the thickness of the base layer is in a range from 10 nm to 50 nm.

12. A method, comprising:
forming a gate layer over a semiconductor substrate in a bipolar junction transistor (BJT) region, a transition region, and a complementary field effect transistor (CFET) region, the transition region being between the BJT region and the CFET region;
forming a first opening through the gate layer at least partially in the BJT region and the transition region, a sidewall of the gate layer defining the first opening being in the transition region;
forming a collector layer in the first opening and on an upper surface of the semiconductor substrate in the BJT region;
forming a base layer on the collector layer;
forming an emitter layer on the base layer; and
after forming the emitter layer, patterning the gate layer into a gate electrode of a field effect transistor (FET) in the CFET region.

13. The method of claim 12, wherein after patterning the gate layer, a portion of the gate layer remains in the transition region, the portion of the gate layer having the sidewall.

14. The method of claim 13, wherein forming the base layer includes:
depositing a material of the base layer; and
etching the material of the base layer into the base layer, wherein a portion of the material of the base layer remains on the sidewall of the gate layer after etching the material of the base layer and after patterning the gate layer into the gate electrode of the FET.

15. The method of claim 12, further comprising:
forming a pedestal dielectric layer over the upper surface of the semiconductor substrate in the BJT region and at least partially in the transition region, the first opening through the gate layer being to the pedestal dielectric layer, the sidewall of the gate layer being over the pedestal dielectric layer; and
forming, through the first opening, a second opening through the pedestal dielectric layer to the upper surface of the semiconductor substrate, the collector layer being formed in the second opening.

16. The method of claim 15, further comprising after patterning the gate layer into the gate electrode of the FET, etching the pedestal dielectric layer to expose the upper surface of the semiconductor substrate in the BJT region.

17. The method of claim 15, wherein the base layer is further formed on the pedestal dielectric layer.

18. The method of claim 12, further comprising, after forming the emitter layer, forming a raised base layer on the base layer.

19. The method of claim 18, further comprising reacting a metal with a semiconductor material of the raised base layer.

20. The method of claim 12, further comprising reacting a metal with a semiconductor material of the base layer.

21. The method of claim 12, wherein:
a thickness of the collector layer does not exceed 200 nm; and
a thickness of the base layer does not exceed 100 nm.

22. A method, comprising:
forming a pedestal dielectric layer over a semiconductor substrate in a bipolar junction transistor (BJT) region and at least partially in a transition region, the transition region being between the BJT region and a complementary field effect transistor (CFET) region;
forming a gate layer over the semiconductor substrate in the BJT region, the transition region, and the CFET region and over the pedestal dielectric layer;
forming a first opening through the gate layer to the pedestal dielectric layer, wherein a sidewall of the gate layer defining at least a portion of the first opening is over the pedestal dielectric layer in the transition region;
forming, through the first opening, a second opening through the pedestal dielectric layer to an upper surface of the semiconductor substrate in the BJT region;
forming, through the first opening, a collector layer in the second opening and on the upper surface of the semiconductor substrate;
forming, through the first opening, a base layer on the collector layer;
forming, through the first opening, an emitter layer on the base layer; and
patterning the gate layer into a gate electrode of a field effect transistor (FET) in the FET region, wherein after patterning the gate layer into the gate electrode of the FET, a portion of the gate layer remains in the transition region.
